(19) United States
(12) Patent Application Publication
(10) Pub. No.: US 2026/0093777 A1
(43) Pub. Date: Apr. 2, 2026

(54) NAND ACCELERATOR FOR VECTOR-VECTOR MULTIPLICATION

(71) Applicant: Sandisk Technologies, Inc., Milpitas, CA (US)

(72) Inventors: Chao Sun, San Jose, CA (US); Muqing Liu, San Jose, CA (US); Cyril Guyot, San Jose, CA (US)

(73) Assignee: Sandisk Technologies, Inc., Milpitas, CA (US)

(21) Appl. No.: 18/905,088

(22) Filed: Oct. 2, 2024

(51) Int. Cl. G06F 17/16; G06F 7/53; G11C 16/10

(52) U.S. Cl. CPC G06F 17/16; G06F 7/53; G11C 16/102

(57) ABSTRACT

Technology for NAND in-memory compute. NAND memory cells are organized into basic compute engines (CE). A basic CE contains a group of NAND memory cells in the same plane in the memory system. A basic CE may be associated with a set of bit lines in the plane. The memory system may map vectors of leaf nodes of one or more trees to basic CEs and program the vectors of the leaf nodes into basic compute engines in accordance with the mapping. The memory system perform an in-memory vector-vector multiplication in parallel between an input vector and each of the vectors of one or more of the leaf nodes in one or more of the basic compute engines.

### BACKGROUND

The present disclosure relates to technology for in-memory computing.

Artificial neural networks are finding increasing usage in artificial intelligence and machine learning applications. In an artificial neural network, a set of inputs is propagated through one or more intermediate, or hidden, layers to generate an output. The layers connecting the input to the output are connected by sets of weights that are generated in a training or learning phase by determining a set of a mathematical manipulations to turn the input into the output, moving through the layers calculating the probability of each output. Once the weights are established, they can be used in the inference phase to determine the output from a set of inputs. Although such neural networks can provide highly accurate results, they are extremely computationally intensive, and the data transfers involved in reading the weights connecting the different layers out of memory and transferring these weights into the processing units of a processing unit can be quite intensive.

Vector-vector operations are a basic operation in the implementation of machine learning algorithms, such as artificial neural networks. Such vector-vector operations typically involve extremely large amounts of data and large numbers of operations. As such, they are extremely computationally intensive, involving large numbers of data transfers and consuming large amounts of time and power.

Nearest neighbor searching is a technique in computer science, but is computationally intensive. For example, for a vector database of N vectors of dimension d, an exact search using a linear scan is of computational order O(Nd), which becomes prohibitive when the number of vectors is large, the size of the vectors is large, or both. To deal with this problem, approximate nearest neighbor search techniques can be used to provide a fast search, but with a tradeoff between accuracy on the one side and runtime and memory-consumption on the other side. Nearest neighbor searches commonly have a search time complexity of O(nd), where n is the number of vectors and d is the dimension of the vector. Nearest neighbor searches find many uses in vector databases and involve computing the distance from a query to each point in the database. Such searches are computationally complex and, for large data sets, computationally prohibitive. To make such computations more manageable it has been proposed to use an approximate nearest search (ANN) to trade accuracy for speed.

However, technical challenges still exist for performing vector-vector multiplication in general. Moreover, technical challenges still exist for vector based nearest neighbor searches.

### BRIEF DESCRIPTION OF THE DRAWINGS

Like-numbered elements refer to common components in the different figures.

FIG. 1 is a block diagram depicting one embodiment of a memory system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 3C is a block diagram depicting one embodiment of a portion of column control circuitry that contains a number of read/write circuits.

FIG. 4 is a perspective view of a portion of one example embodiment of a monolithic three dimensional memory structure.

FIG. 4A is a block diagram of one embodiment of a memory structure having two planes.

FIG. 4B is a block diagram depicting a top view of a portion of block of memory cells.

FIG. 4C depicts an embodiment of a stack showing a cross-sectional view along line AA of FIG. 4B.

FIG. 4D depicts a view of the region 445 of FIG. 4C.

FIG. 4E is a schematic diagram of a portion of one embodiment of a block, depicting several NAND strings.

FIG. 5 is a flowchart describing one embodiment of a process for programming memory cells connected to a selected word line.

FIG. 6A illustrates a simple example of a convolutional neural network (CNN).

FIG. 6B illustrates a simple example of fully connected layers in an artificial neural network.

FIGS. 7A and 7B illustrates some elements of an example of a transformer model of deep neural network (DNN).

FIG. 8A is a flowchart describing one embodiment of a process for training a neural network to generate a set of weights.

FIG. 8B is a flowchart describing one embodiment of a process for inference using a neural network.

FIG. 9 is a schematic representation of a convolution operation in a convolutional neural network.

FIG. 10 is a schematic representation of the use of matrix multiplication in a fully connected layer of an artificial neural network.

FIGS. 11 and 12 schematically illustrate vector-matrix multiplications, which are a basic computation unit of a deep neural network (DNN).

FIG. 13A illustrates an embodiment for the multiplication of a vector and a matrix using a 3D NAND structure in which the input vector is applied to the word lines.

FIG. 13B illustrates a timing based method for analog values matrix-vector multiplication.

FIG. 14 is a flowchart for an embodiment of operating a 3D NAND multiply and accumulate engine.

FIGS. 15A, 15B, 15C, and 15D are diagrams showing a general overview of ANNOY.

FIG. 16 depicts a simplified example tree that may be used in an ANN.

FIG. 17 depicts one embodiment of an accelerate card that may be used for ANN.

FIG. 18 depicts using a basic compute engine (CE) in NAND to perform parallel vector-vector multiplication.

FIG. 19 shows an example in which the basic CE is programmed with vectors from leaf nodes from different trees.

FIG. 20 is a block level diagram showing one example of how a plane may contain many basic CEs.

FIG. 21 is a block level diagram showing another example of how a plane may contain many basic CEs.

FIG. 22 shows an embodiment having meta CEs.

FIGS. 23A and 23B show embodiments for in-memory compute of vectors, which may be used to calculate distances between vectors.

FIG. 24 is a flowchart of one embodiment of a process of mapping vectors to basic CEs.

FIG. 25 is a flowchart of one embodiment of a process of an ANN search.

FIG. 26 is a flowchart of one embodiment of a process that shows further details of determining distances between the input vector and vectors in a leaf node based on the vector-vector multiplication.

FIG. 27 illustrates how vectors of leaf node may be stored in a basic CE.

FIG. 28 is a flowchart of an embodiment of a process of locating actual vectors based on the computation results.

FIGS. 29A, 29B, and 29C depict results after various steps in the process of FIG. 28.

### DETAILED DESCRIPTION

Technology is disclosed for in-memory computing. Vector-vector multiply operations can be efficiently performed by in-memory compute operations. As one example, NAND memory cells on a set of NAND strings may be programmed to states that represent vectors in, for example, a vector database. The memory system determines signals to represent an input vector and then applies those signals to the set of NAND strings. The memory system senses bit lines associated with the set of NAND strings and then determines results for vector-vector multiplies based on sensing the bit lines. Based on the vector-vector multiplies, the memory system may determine a distance between the input vector and each of the vectors programmed into the NAND memory cells on a set of NAND strings.

In an embodiment, the NAND memory cells are organized into basic compute engines (CE). A basic CE contains a group of NAND memory cells in the same plane in the memory system. In an embodiment, a basic CE is associated with a set of bit lines in the plane. There may be many basic CEs in the plane. The memory system may program a group of vectors into a basic CE. The memory system may apply signals that represent an input vector to the basic CE and sense the bit lines associated with the basic CE to perform a large number of vector-vector multiplications in parallel. In one embodiment, the memory system selects a single basic CE in a plane for vector-vector multiply. However, additional parallelism can be achieved by performing vector-vector multiplication in parallel in one basic CE in each of a number of planes in the NAND memory system.

In an embodiment, the parallel vector-vector multiply is used in an approximate nearest neighbor (ANN) search. The memory system maps vectors in a vector database to the basic CEs. In one embodiment, the memory system forms one or more trees with each tree having intermediate nodes and leaf nodes. The trees are data structures that may be stored in memory such as NAND memory cells or random access memory such as DRAM. Each leaf node has a number of vectors. The memory system may map the leaf node vectors to the basic CEs in an efficient manner having a high utilization of NAND memory cells. The memory system may map the leaf node vectors to the basic CEs in a manner that allows for massive parallelism of vector-vector multiply. Therefore, approximate nearest neighbor search is performed quickly.

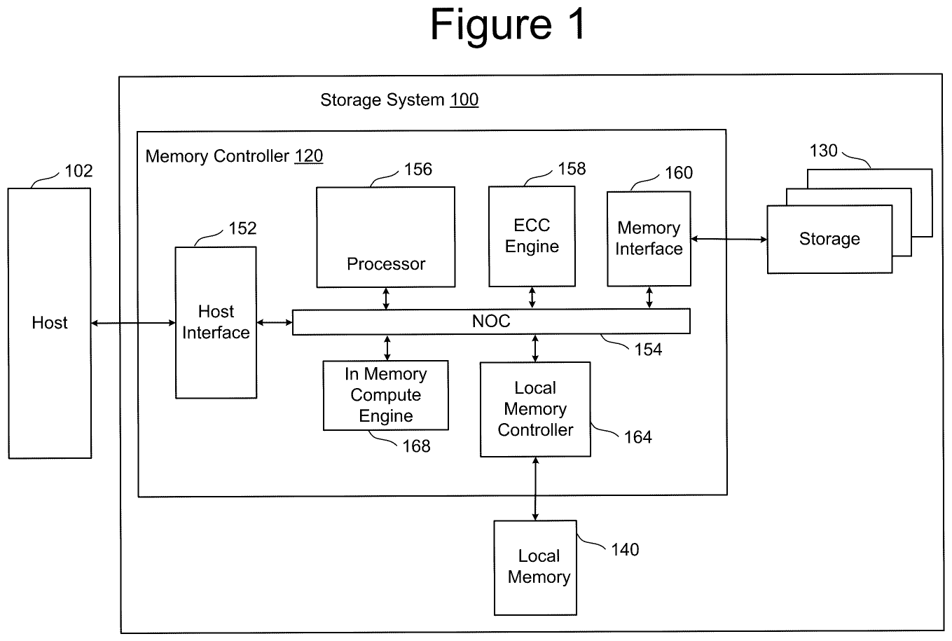

FIG. 1 is a block diagram of one embodiment of a memory system 100 that implements the technology described herein. In one embodiment, memory system 100 performs in-memory computing. In one embodiment, memory system 100 performs approximate nearest neighbor search, which may include performing parallel vector-vector multiply in the storage 130. In one embodiment, memory system 100 is a solid state drive (“SSD”). Memory system 100 can also be a memory card, USB drive or other type of memory system. The proposed technology is not limited to any one type of memory system. Memory system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, memory system 100. In other embodiments, memory system 100 is embedded within host 102.

The components of memory system 100 depicted in FIG. 1 are electrical circuits. Memory system 100 includes a memory controller 120 (or storage controller) connected to non-volatile storage 130 and local high speed memory 140 (e.g., DRAM, SRAM, MRAM). Local memory 140 is non-transitory memory, which may include volatile memory or non-volatile memory. Non-volatile storage includes non-transitory memory such as NAND memory cells. Local high speed memory 140 is used by memory controller 120 to perform certain operations. For example, local high speed memory 140 may store logical to physical address translation tables (“L2P tables”).

Memory controller 120 comprises a host interface 152 that is connected to and in communication with host 102. In one embodiment, host interface 152 implements an NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and local memory controller 164. Local memory controller 164 is used to operate and communicate with local high speed memory 140 (e.g., DRAM, SRAM, MRAM).

ECC engine 158 performs error correction services. For example, ECC engine 158 performs data encoding and decoding. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156. In an embodiment in which memory controller 120 oversees in-memory compute in storage 130, the ECC engine 158 is not needed for data encoding and decoding.

Processor 156 performs the various controller memory operations such as programming, erasing, reading, and memory management processes. The in-memory compute engine 168 oversees in-memory compute in the storage 130 and/or local memory 140. The in-memory compute engine 168 may program vectors of a vector database into memory cells in storage 130 and/or local memory 140. The in-memory compute engine 168 may provide input vectors to storage 130 and/or local memory during in-memory compute. Although depicted as separated from the processor 156, the in-memory compute engine 168 may be implemented by the processor 156. In one embodiment, processor 156 is programmed by firmware. In other embodiments, processor 156 is a custom and dedicated hardware circuit without any software. In some embodiments, the storage 130 is used only for in-memory compute. In some embodiments, the storage 130 is used for both in-memory compute and host storage. The following will describe an option to use a portion of storage for host storage. Processor 156 may also implement a translation module, as a software/firmware process or as a dedicated hardware circuit. In many systems, the non-volatile memory is addressed internally to the memory system using physical addresses associated with the one or more memory die. However, the host system will use logical addresses to address the various memory locations. This enables the host to assign data to consecutive logical addresses, while the memory system is free to store the data as it wishes among the locations of the one or more memory die. To implement this system, memory controller 120 (e.g., the translation module) performs address translation between the logical addresses used by the host and the physical addresses used by the memory die. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a memory system is so large that the local memory 140 cannot hold all of the L2P tables. In such a case, the entire set of L2P tables are stored in a storage 130 and a subset of the L2P tables are cached (L2P cache) in the local high speed memory 140.

Memory interface 160 communicates with non-volatile storage 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

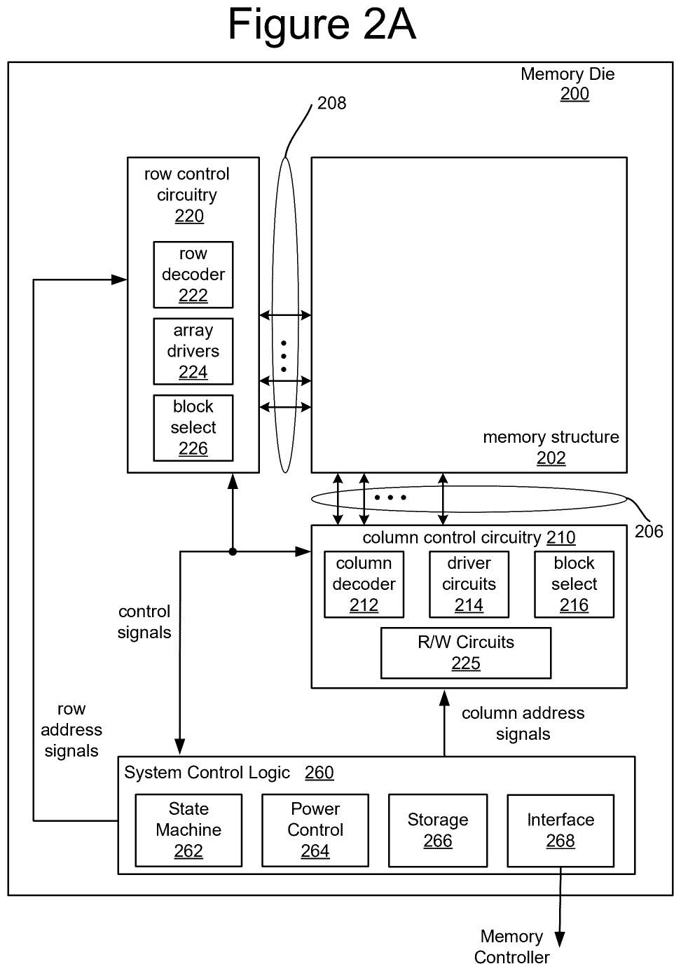

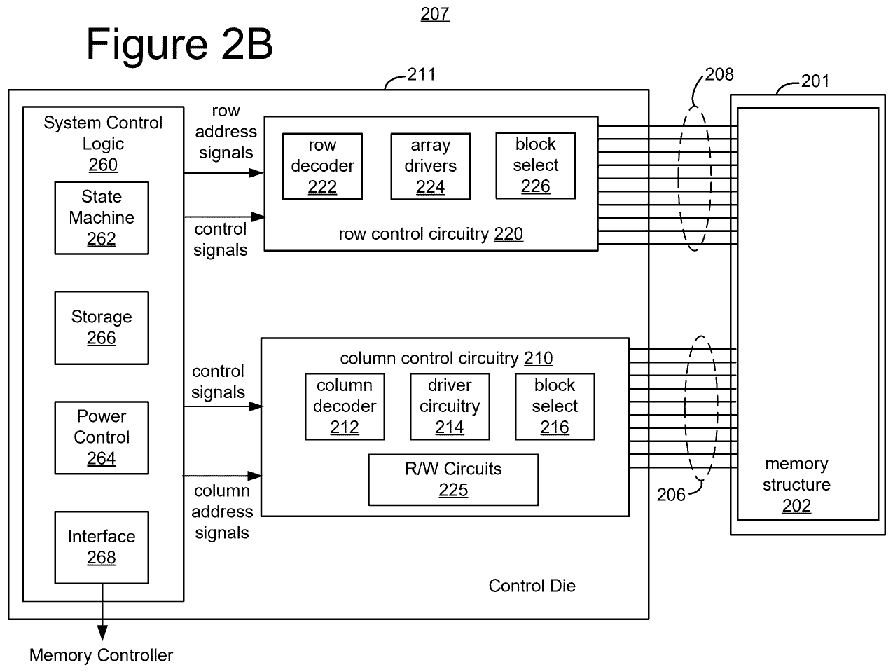

In one embodiment, non-volatile storage 130 comprises one or more memory dies. FIG. 2A is a functional block diagram of one embodiment of a memory die 200 that comprises non-volatile storage 130. Each of the one or more memory dies of non-volatile storage 130 can be implemented as memory die 200 of FIG. 2A. The components depicted in FIG. 2A are electrical circuits. Memory die 200 includes a memory structure 202 (e.g., memory array) that can comprise non-volatile memory cells (also referred to as non-volatile storage cells), as described in more detail below. The array terminal lines of memory structure 202 include the various layer(s) of word lines organized as rows, and the various layer(s) of bit lines organized as columns. However, other orientations can also be implemented. Memory die 200 includes row control circuitry 220, whose outputs are connected to respective word lines of the memory structure 202. Row control circuitry 220 receives a group of M row address signals and one or more various control signals from System Control Logic circuit 260, and typically may include such circuits as row decoders 222, array drivers 224, and block select circuitry 226 for both reading and writing (programming) operations. Row control circuitry 220 may also include read/write circuitry. Memory die 200 also includes column control circuitry 210 including read/write circuits 225. The read/write circuits 225 may contain sense amplifiers and data latches. The sense amplifier(s) input/outputs are connected to respective bit lines of the memory structure 202. Although only single block is shown for structure 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers. The system control logic 260, column control circuitry 210, and/or row control circuity 220 are configured to control memory operations such as open block reads at the die level.

System control logic 260 receives data and commands from memory controller 120 and provides output data and status to the host. In an embodiment the data includes vectors to program into memory cells in the memory structure 202. In an embodiment the output data includes computation results from an in-memory compute, such as vector-vector multiply. In some embodiments, the system control logic 260 (which comprises one or more electrical circuits) includes state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations. System control logic 260 includes storage 266 (e.g., RAM, registers, latches, etc.), which may be used to store parameters for operating the memory structure 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die than the die that contains the memory structure 202.

In one embodiment, memory structure 202 comprises a three-dimensional memory array of non-volatile memory cells in which multiple memory levels are formed above a single substrate, such as a wafer. The memory structure may comprise any type of non-volatile memory that are monolithically formed in one or more physical levels of memory cells having an active area disposed above a silicon (or other type of) substrate. In one example, the non-volatile memory cells comprise vertical NAND strings with charge-trapping layers.

In another embodiment, memory structure 202 comprises a two-dimensional memory array of non-volatile memory cells. In one example, the non-volatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular non-volatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or other wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of memory system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the memory system 100 is the amount of area to devote to the memory structure 202 and the amount of area to devote to the peripheral circuitry.

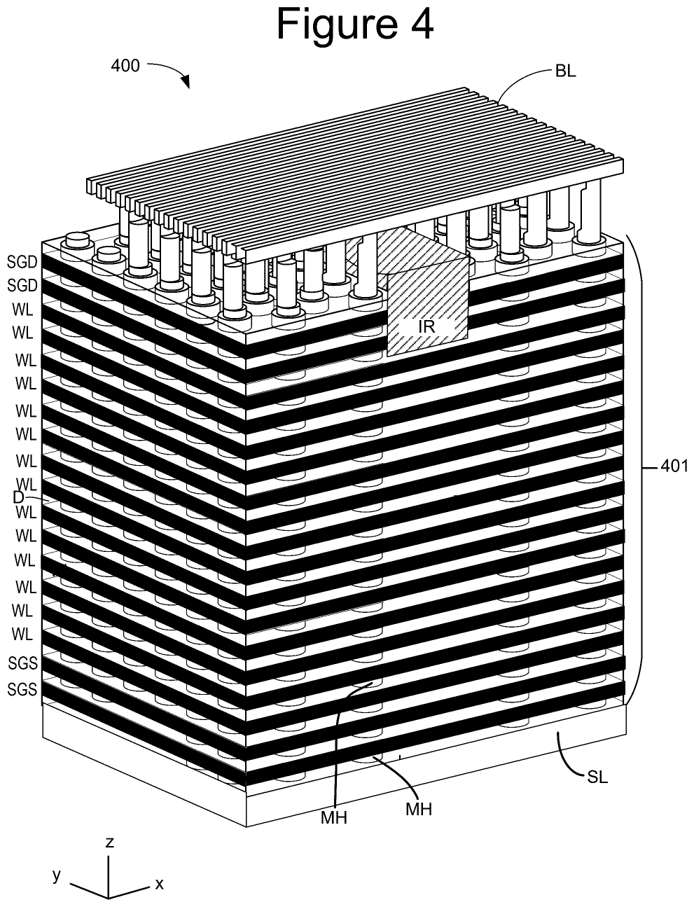

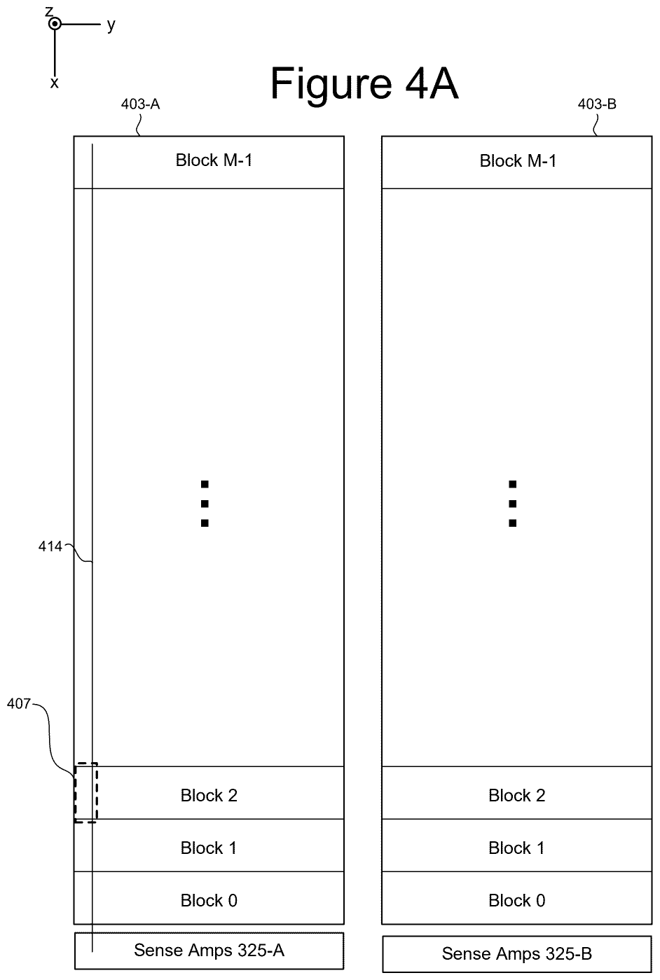

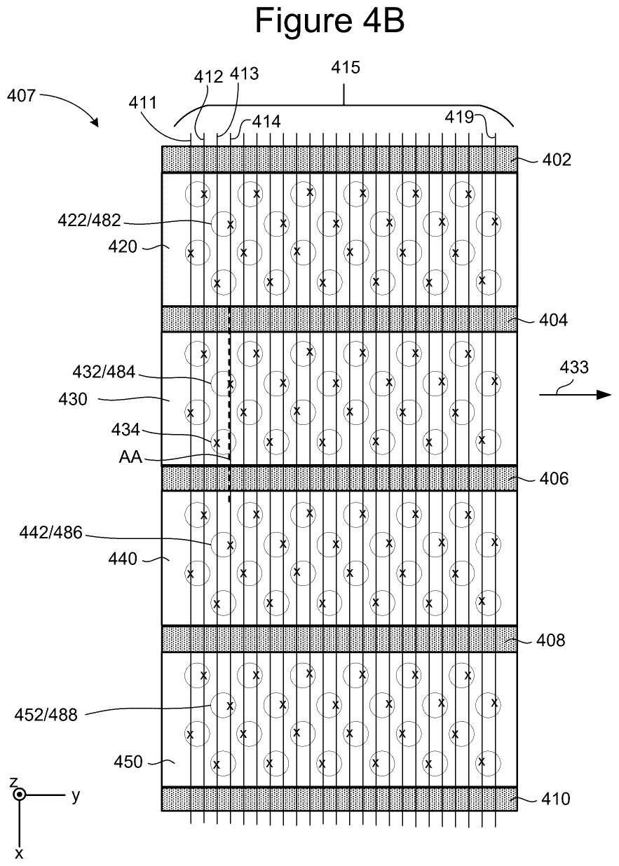

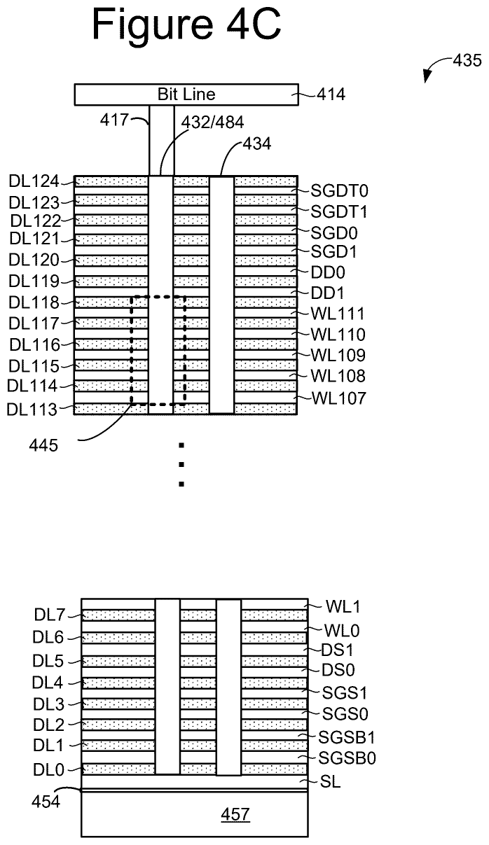

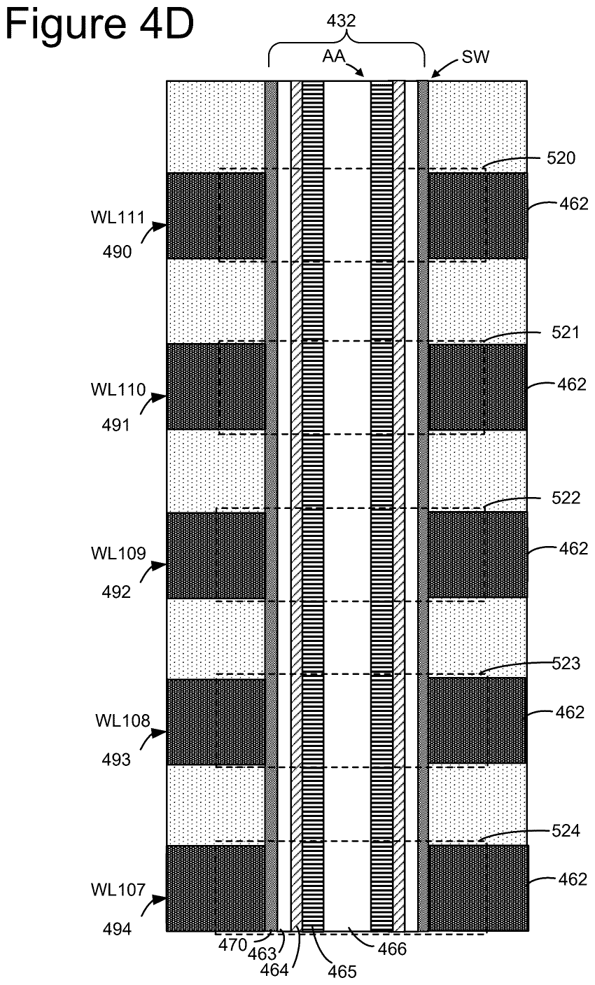

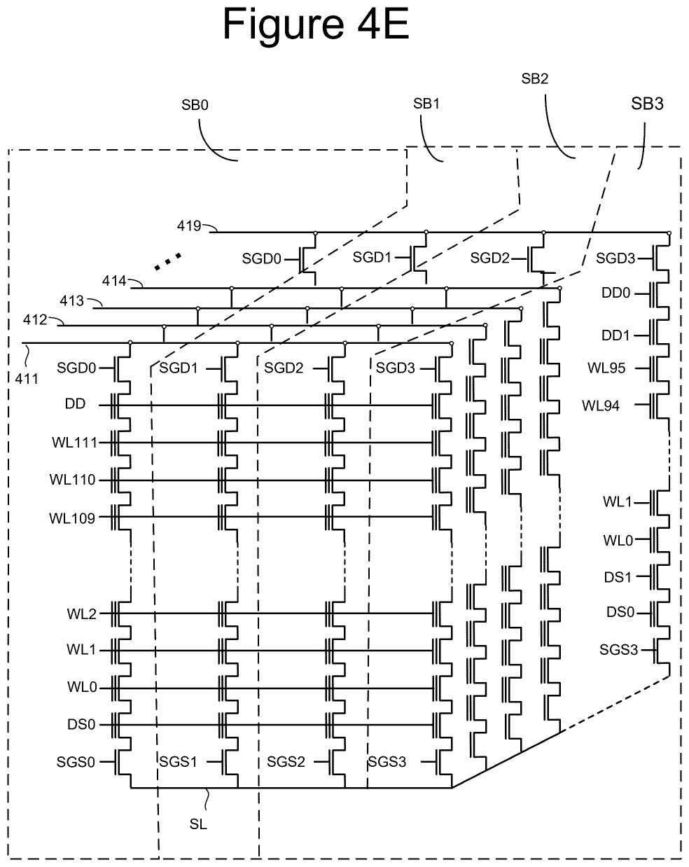

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies. Three-dimensional NAND structures (see, for example, FIG. 4) in particular may benefit from specialized processing operations.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more dies, such as two memory dies and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the non-volatile storage 130 of memory system 100. The integrated memory assembly 207 includes two types of semiconductor dies (or more succinctly, “die”). Memory structure die 201 includes memory structure 202. Memory structure 202 includes non-volatile memory cells. Control die 211 includes control circuitry 260, 210, and 220 (as described above). In some embodiments, control die 211 is configured to connect to the memory structure 202 in the memory structure die 201. In some embodiments, the memory structure die 201 and the control die 211 are bonded together.

FIG. 2B shows an example of the peripheral circuitry, including control circuits, formed in a peripheral circuit or control die 211 coupled to memory structure 202 formed in memory structure die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory structure die 201. In some embodiments, some of the circuitry in the system control logic 260 is located on the on the memory structure die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory structure die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including read/write circuits 225 on the control die 211 coupled to memory structure 202 on the memory structure die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory structure die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each electrical path 208 may correspond to a word line, dummy word line, or select gate line. Additional electrical paths may also be provided between control die 211 and memory structure die 201.

For purposes of this document, the phrases “a control circuit” or “one or more control circuits” can include any one of or any combination of memory controller 120, all or a portion of system control logic 260, all or a portion of row control circuitry 220, all or a portion of column control circuitry 210, read/write circuits 225, sense amps, a microcontroller, a microprocessor, and/or other similar functioned circuits. A control circuit can include hardware only or a combination of hardware and software (including firmware). For example, a controller programmed by firmware to perform the functions described herein is one example of a control circuit. A control circuit can include a processor, FPGA, ASIC, integrated circuit, or other type of circuit.

For purposes of this document, the term “apparatus” can include, but is not limited to, one or more of, memory system 100, memory controller 120, storage 130, memory die 200, integrated memory assembly 207, and/or control die 211.

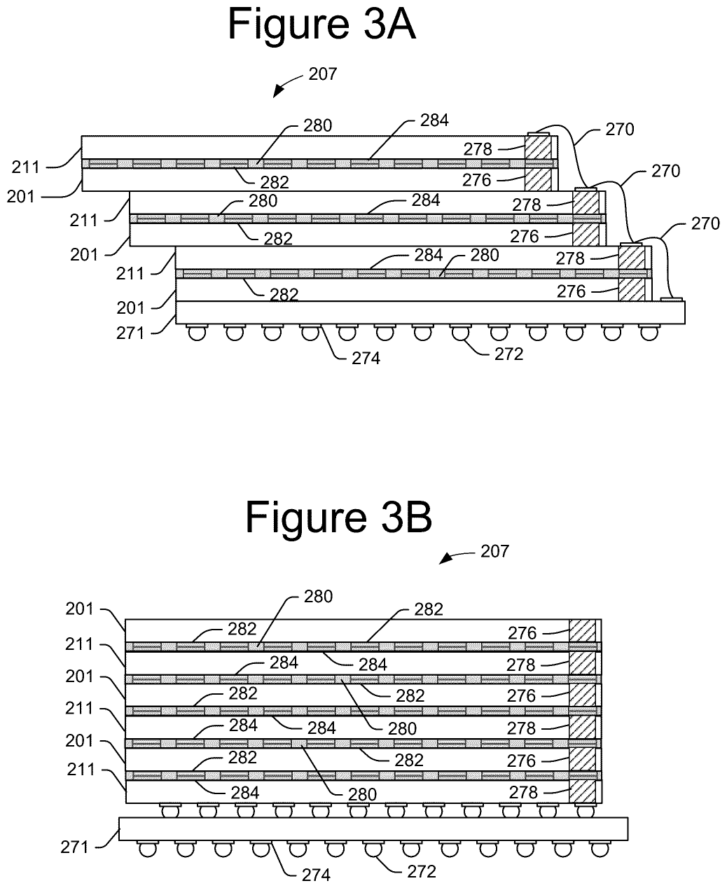

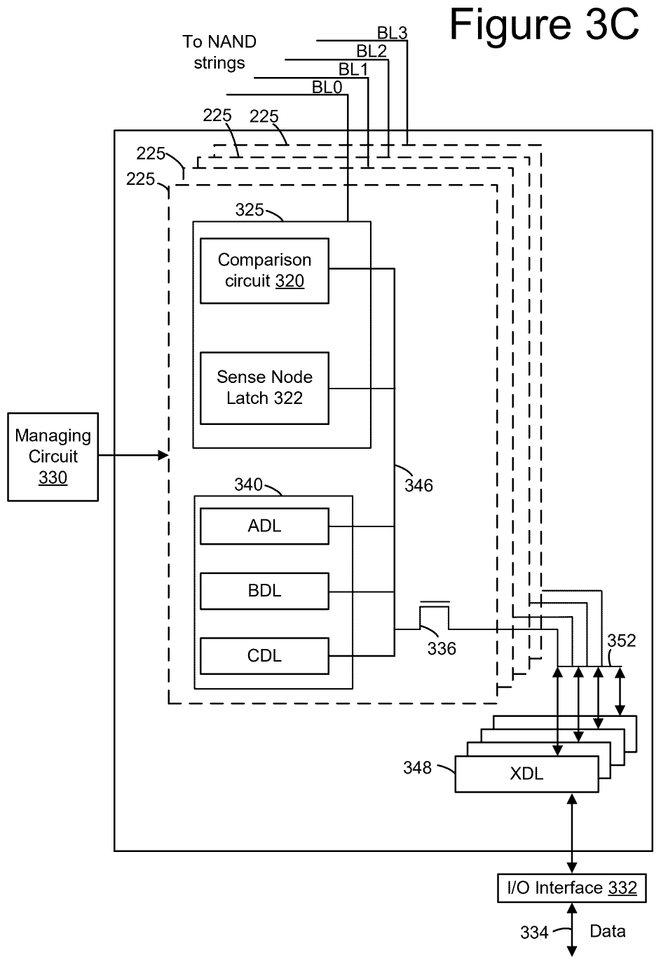

In some embodiments, there is more than one control die 211 and more than one memory structure die 201 in an integrated memory assembly 207. In some embodiments, the integrated memory assembly 207 includes a stack of multiple control dies 211 and multiple memory structure dies 201. FIG. 3A depicts a side view of an embodiment of an integrated memory assembly 207 stacked on a substrate 271 (e.g., a stack comprising control die 211 and memory structure die). The integrated memory assembly 207 has three control dies 211 and three memory structure dies 201. In some embodiments, there are more than three memory structure dies 201 and more than three control dies 211. In FIG. 3A there are an equal number of memory structure dies 201 and control dies 211; however, in one embodiment, there are more memory structure dies 201 than control dies 211. For example, one control die 211 could control multiple memory structure dies 201.

Each control die 211 is affixed (e.g., bonded) to at least one of the memory structure die 201. Some of the bond pads 282/284 are depicted. There may be many more bond pads. A space between two die 201, 211 that are bonded together is filled with a solid layer 280, which may be formed from epoxy or other resin or polymer. This solid layer 280 protects the electrical connections between the die 201, 211, and further secures the die together. Various materials may be used as solid layer 280.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory structure die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control dies 211 and three memory structure dies 201. In some embodiments, there are many more than three memory structure dies 201 and many more than three control dies 211. In this example, each control die 211 is bonded to at least one memory structure die 201. Optionally, a control die 211 may be bonded to two or more memory structure dies 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory structure die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory structure die 201 may be bonded together. Bond pads on each die 201, 211 may be used to bond the two die together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor die including the bond pads. The film layer is provided around the bond pads. When the die are brought together, the bond pads may bond to each other, and the film layers on the respective die may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller sizes and pitches.

Some embodiments may include a film on surface of the dies 201, 211. Where no such film is initially provided, a space between the die may be under filled with an epoxy or other resin or polymer. The under-fill material may be applied as a liquid which then hardens into a solid layer. This under-fill step protects the electrical connections between the dies 201, 211, and further secures the die together. Various materials may be used as under-fill material.

FIG. 3C is a block diagram depicting one embodiment of a portion of column control circuitry 210 that contains a number of read/write circuits 225. Each read/write circuit 225 is partitioned into a sense amplifier 325 and data latches 340. A managing circuit 330 controls the read/write circuits 225. The managing circuit 330 may communicate with state machine 262. In one embodiment, each sense amplifier 325 is connected to a respective bit line. Each bit line may be connected, at one point in time, to one of a large number of different NAND strings. A select gate on the NAND string may be used to connect the NAND string channel to the bit line.

Each sense amplifier 325 operates to provide voltages to one of the bit lines (see BL0, BL1, BL2, BL3) during program, verify, erase, read, and in-memory compute operations. Sense amplifiers are also used to sense the condition (e.g., data state) of a memory cell in a NAND string connected to the bit line that connects to the respective sense amplifier. The following will discuss use of the sense amplifier 325 to sense a condition (e.g., data state) of a memory cell. Sense amplifiers may also be used to sense bit line currents during in-memory compute (e.g., MAC, vector-vector multiply, VMM). Such in-memory compute sense amplifiers may have a variety of implementations and are not limited to the example in FIG. 3C.

Each sense amplifier 325 may have a sense node. During sensing, a sense node is charged up to an initial voltage, Vsense_init, such as 3V. The sense node is then connected to the bit line for a sensing time, and an amount of decay of the sense node is used to determine whether a memory cell is in a conductive or non-conductive state. The amount of decay of the sense node also indicates whether a current Icell in the memory cell exceeds a reference current, Iref. A larger decay corresponds to a larger current. If Icell<=Iref, the memory cell is in a non-conductive state and if Icell>Iref, the memory cell is in a conductive state. In an embodiment, the sense node has a capacitor that is pre-charged and then discharged for the sensing time.

In particular, the comparison circuit 320 determines the amount of decay by comparing the sense node voltage to a trip voltage after the sensing time. If the sense node voltage decays below the trip voltage, Vtrip, the memory cell is in a conductive state and its Vth is at or below the verify voltage. If the sense node voltage does not decay below Vtrip, the memory cell is in a non-conductive state and its Vth is above the program verify voltage. A sense node latch 322 is set to 0 or 1, for example, by the comparison circuit 320 based on whether the memory cell is in a conductive or non-conductive state, respectively. The bit in the sense node latch 322 can also be used in a lockout scan to decide whether to set a bit line voltage to an inhibit or a program enable level in a next program loop. The bit in the sense node latch 322 can also be used in a lockout mode to decide whether to set a bit line voltage to a sense voltage or a lockout voltage in a read operation.

The data latches 340 are coupled to the sense amplifier 325 by a local data bus 346. The data latches 340 include three latches (ADL, BDL, CDL) for each sense amplifier 325 in this example. More or fewer than three latches may be included in the data latches 340. In one embodiment, for programming each data latch 340 is used to store one bit to be stored into a memory cell and for reading each data latch 340 is used to store one bit read from a memory cell. In a three bit per memory cell embodiment, ADL stores a bit for a lower page of data, BDL stores a bit for a middle page of data, CDL stores a bit for an upper page of data. Each read/write circuit 225 is connected to an XDL latch 348 by way of an XDL bus 352. In this example, transistor 336 connects local data bus 346 to XDL bus 352. An I/O interface 332 is connected to the XDL latches 348. The XDL latch 348 associated with a particular read/write circuit 225 serves as an interface latch for storing/latching data from the memory controller.

Managing circuit 330 performs computations, such as to determine the data stored in the sensed memory cell and store the determined data in the set of data latches. Each set of data latches 340 is used to store data bits determined by managing circuit 330 during a read operation, and to store data bits imported from the data bus 334 during a program operation which represent write data meant to be programmed into the memory. I/O interface 332 provides an interface between XDL latches 348 and the data bus 334.

During reading, the operation of the system is under the control of state machine 262 that controls the supply of different control gate voltages to the addressed memory cell. As it steps through the various predefined control gate voltages corresponding to the various memory states supported by the memory, the sense circuit may trip at one of these voltages and a corresponding output will be provided from the sense amplifier to managing circuit 330. At that point, managing circuit 330 determines the resultant memory state by consideration of the tripping event(s) of the sense circuit and the information about the applied control gate voltage from the state machine. It then computes a binary encoding for the memory state and stores the resultant data bits into data latches 340.

During program or verify operations for memory cells, the data to be programmed (write data) is stored in the set of data latches 340 from the data bus 334 by way of XDL latches 348. The program operation, under the control of the state machine 262, applies a series of programming voltage pulses to the control gates of the addressed memory cells. Each voltage pulse may be stepped up in magnitude from a previous program pulse by a step size in a process referred to as incremental step pulse programming. In one embodiment, each program voltage is followed by a verify operation to determine if the memory cells have been programmed to the desired memory state. In some cases, managing circuit 330 monitors the read back memory state relative to the desired memory state. When the two agree, managing circuit 330 sets the bit line in a program inhibit mode such as by updating its latches. This inhibits the memory cell coupled to the bit line from further programming even if additional program pulses are applied to its control gate.

FIG. 4 is a perspective view of a portion of one example embodiment of a monolithic three dimensional memory array/structure that can comprise memory structure 202, which includes a plurality non-volatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D. The conductive layers are labeled as one of: SGD, WL, or SGS. An SGD conductive layer serves as drain side select lines. A WL conductive layer serves as a word line. An SGS conductive layer serves as a source side select line. The numbers of each of these conductive layers is limited for ease of illustration. The number of alternating dielectric layers and conductive layers can vary based on specific implementation requirements. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. More details of the three dimensional monolithic memory array that comprises memory structure 202 is provided below.

In one embodiment the block is operated as a number of “sub-blocks.” Each of these “sub-blocks” has many NAND strings. In an embodiment, an isolation region (IR) divides the SGD layers into multiple SGD select lines, each of which is used to select a sub-block (e.g., set of NAND strings). FIG. 4 depicts an example having one IR region and thereby two sub-blocks. However, there may be more than one IR region and thereby more than two sub-blocks. Optionally, the IR region can extend down through all of the alternating dielectric layers and conductive layers.

FIG. 4A is a block diagram explaining one example organization of memory structure 202, which is divided into two planes 403-A and 403-B. Each plane 403 is then divided into M physical blocks. In one example, each plane has about 2000 physical blocks (or more briefly “blocks”). However, different numbers of blocks and planes can also be used. In one “full-block” embodiment, a block of memory cells is a unit of erase. That is, all memory cells of a block are erased together. In a “sub-block mode” embodiment, blocks are divided into sub-blocks and the sub-blocks are the unit of erase. In an embodiment, a block contains a number of word lines with each sub-block containing a unique set of the data word lines. In an embodiment, each plane 403-A, 403-B has a set of bit lines that extend across all of the blocks in that plane. In an embodiment, one block per plane is selected at a time for operations such as read or program. In an embodiment, one block per plane is selected at a time for in-memory compute (which may be the case if the basic CE is within a single block). In an embodiment, multiple blocks per plane are selected at a time for in-memory compute (which may be the case if the basic CE is within the multiple blocks). In an embodiment, the memory system select a single CE within a plane at a time for in-memory compute. However, additional parallelism may be achieved by selecting a CE within each plane 403-A, 403B for in-memory compute.

Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows two planes 403-A, 403-B more or fewer than two planes can be implemented. In some embodiments, memory structure 202 includes four planes. In some embodiments, memory structure 202 includes eight planes. In some embodiments, programming can be performed in parallel in a first selected block in plane 403-A and a second selected block in plane 403-B.

A first group of sense amplifiers 325-A are associated with plane 403-A, and a second group of sense amplifiers 325-B are associated with plane 403-B. The sense amplifiers 325-A, 325-B may be on the same die as the memory cells or on a different die than the memory cells. For example, in an architecture depicted in FIG. 2A, the sense amplifiers are in R/W circuits 225 on the memory die 200 with the memory structure 202. However, for an architecture depicted in FIG. 2B, the sense amplifiers are in R/W circuits 225 on the control die 211, which is separate from the memory structure die 201 that contains the memory structure 202. Each sense amplifier 325 may be associated with a bit line. One example bit line 414 is depicted. The sense amplifier 325 may provide a voltage to one end of the bit line 414 during memory operations such as program, read, and in-memory compute. The bit line 414 is physically connected to many different NAND strings in a plane 403. In an embodiment, the bit line 414 is physically connected to several NAND strings in each block. The channel of a NAND string is electrically connectable to a bit line. For typical program and read operations, the bit line 414 is electrically connected to the channel of one NAND string in the plane 403-A, with the channels of other NAND strings disconnected electrically from the bit line.

FIGS. 4B-4E depict an example three dimensional (“3D”) NAND structure that corresponds to the structure of FIG. 4 and can be used to implement memory structure 202 of FIGS. 2A and 2B. FIG. 4B is a diagram depicting a top view of a portion 407 of Block 2. As can be seen from FIG. 4B, the physical block depicted in FIG. 4B extends in the direction of arrow 433. In one embodiment, the memory array has many layers; however, FIG. 4B only shows the top layer.

FIG. 4B depicts a plurality of circles that represent the vertical columns. Each of the vertical columns include multiple select transistors (also referred to as a select gate or selection gate) and multiple memory cells. In one embodiment, each vertical column implements a NAND string. For example, FIG. 4B depicts vertical columns 422, 432, 442, and 452. Vertical column 422 implements NAND string 482. Vertical column 432 implements NAND string 484. Vertical column 442 implements NAND string 486. Vertical column 452 implements NAND string 488. More details of the vertical columns are provided below. Since the physical block depicted in FIG. 4B extends in the direction of arrow 433, the physical block includes more vertical columns than depicted in FIG. 4B.

FIG. 4B also depicts a set of bit lines 415, including bit lines 411, 412, 413, 414, . . . 419. FIG. 4B shows twenty-four bit lines because only a portion of the physical block is depicted. It is contemplated that more than twenty-four bit lines connected to vertical columns of the physical block. Each of the circles representing vertical columns has an “x” to indicate its connection to one bit line. For example, bit line 414 is connected to vertical columns 422, 432, 442 and 452. The bit lines 415 may also extend over other blocks in the plane.

The physical block depicted in FIG. 4B includes a set of isolation regions 402, 404, 406, 408, and 410, which are formed of SiO₂; however, other dielectric materials can also be used. Isolation regions 402, 404, 406, 408, and 410 serve to divide the top layers of the physical block into four regions; for example, the top layer depicted in FIG. 4B is divided into regions 420, 430, 440, and 450, which are referred to herein as “sub-blocks.” Each sub-block contains a large number of NAND strings. In one embodiment, isolation regions 402 and 410 separate the physical block 407 from adjacent physical blocks. Thus, isolation regions 402 and 410 may extend down to the substrate. In one embodiment, the isolation regions 404, 406, and 408 only divide the layers used to implement select gates so that NAND strings in different sub-blocks can be independently selected. Referring back to FIG. 4, the IR region may correspond to any of isolation regions 404, 406, or 408. In one example implementation, a bit line only connects to one vertical column/NAND string in each of regions (sub-blocks) 420, 430, 440, and 450. In that implementation, each physical block has sixteen rows of active columns and each bit line connects to four NAND strings in each block. In one embodiment, all of the four vertical columns/NAND strings connected to a common bit line are connected to the same word line (or set of word lines); therefore, the system uses the drain side selection lines to choose one (or another subset) of the four to be subjected to a memory operation (program, verify, read, erase, and/or in-memory compute).

Although FIG. 4B shows each region (420, 430, 440, 450) having four rows of vertical columns, four regions (420, 430, 440, 450) and sixteen rows of vertical columns in a block, those exact numbers are an example implementation. Other embodiments may include more or fewer regions (420, 430, 440, 450) per block, more or fewer rows of vertical columns per region and more or fewer rows of vertical columns per block. FIG. 4B also shows the vertical columns being staggered. In other embodiments, different patterns of staggering can be used. In some embodiments, the vertical columns are not staggered.

FIG. 4C depicts an example of a stack 435 showing a cross-sectional view along line AA of FIG. 4B. The SGD layers include SGDT0, SGDT1, SGD0, and SGD1. The SGD layers may have more or fewer than four layers. The SGS layers includes SGSB0, SGSB1, SGS0, and SGS1. The SGS layers may have more or fewer than four layers. Six dummy word line layers DD0, DD1, WLIFDU, WLIDDL, DS1, and DS0 are provided, in addition to the data word line layers WL0-WL111. There may be more or fewer than 112 data word line layers and more or fewer than four dummy word line layers. Each NAND string has a drain side select gate at the SGD layers. Each NAND string has a source side select gate at the SGS layers. Also depicted are dielectric layers DL0-DL124.

Columns 432, 434 of memory cells are depicted in the multi-layer stack. The stack includes a substrate 457, an insulating film 454 on the substrate, and a portion of a source line SL. A portion of the bit line 414 is also depicted. Note that NAND string 484 is connected to the bit line 413. NAND string 484 has a source-end at a bottom of the stack and a drain-end at a top of the stack. The source-end is connected to the source line SL. A conductive via 417 connects the drain-end of NAND string 484 to the bit line 414. The channel of the NAND string 484 may be connected to or disconnected from the bit line 414 by operation of the drain side select gates (SGD).

In one embodiment, the memory cells are arranged in NAND strings. The word line layers WL0-WL111 connect to memory cells (also called data memory cells). Dummy word line layers DD0, DD1, DS0 and DS1 connect to dummy memory cells. A dummy memory cell does not store and is not eligible to store host data (data provided from the host, such as data from a user of the host), while a data memory cell is eligible to store host data. In some embodiments, data memory cells and dummy memory cells may have the same structure. Drain side select layers SGD are used to electrically connect and disconnect (or cut off) the channels of respective NAND strings from bit lines. Source side select layers SGS are used to electrically connect and disconnect (or cut off) the channels of respective NAND strings from the source line SL.

In some embodiments, the stack 435 is divided into two or more tiers. A two or other multi-tier stack can be used to form a relatively tall stack while maintaining a relatively narrow memory hole width (or diameter). After the layers of the lower tier are formed, memory hole portions are formed in the lower tier. Subsequently, after the layers of the upper tier are formed, memory hole portions are formed in the upper tier, aligned with the memory hole portions in the lower tier to form continuous memory holes from the bottom to the top of the stack. The resulting memory hole is narrower than would be the case if the hole were etched from the top to the bottom of the stack rather than in each tier individually. An interface (IF) region is created where the two tiers are connected. The IF region is typically thicker than the other dielectric layers. Due to the presence of the IF region, the adjacent word line layers suffer from edge effects such as difficulty in programming or erasing. These adjacent word line layers can therefore be set as dummy word lines. In some embodiments, the tiers are erased independent of one another. Hence, data may be maintained in the upper tier after the lower tiers is erased. Likewise, data may be maintained in the lower tier after the upper tier is erased.

FIG. 4D depicts a view of the region 445 of FIG. 4C. Data memory cell transistors 520, 521, 522, 523, and 524 are indicated by the dashed lines. A number of layers can be deposited along the sidewall (SW) of the memory hole 432 and/or within each word line layer, e.g., using atomic layer deposition. For example, each column (e.g., the pillar which is formed by the materials within a memory hole) can include a blocking oxide/block high-k material 470, charge-trapping layer or film 463 such as SiN or other nitride, a tunneling layer 464, a polysilicon body or channel 465, and a dielectric core 466. A word line layer can include a conductive metal 462 such as Tungsten as a control gate. For example, control gates 490, 491, 492, 493 and 494 are provided. In this example, all of the layers except the metal are provided in the memory hole. In other approaches, some of the layers can be in the control gate layer. Additional pillars are similarly formed in the different memory holes. A pillar can form a columnar active area (AA) of a NAND string.

When a data memory cell transistor is programmed, electrons are stored in a portion of the charge-trapping layer which is associated with the data memory cell transistor. These electrons are drawn into the charge-trapping layer from the channel, and through the tunneling layer. The Vth of a data memory cell transistor is increased in proportion to the amount of stored charge. During an erase operation, the electrons return to the channel.

Each of the memory holes can be filled with a plurality of annular layers (also referred to as memory film layers) comprising a blocking oxide layer, a charge trapping layer, a tunneling layer and a channel layer. A core region of each of the memory holes is filled with a body material, and the plurality of annular layers are between the core region and the WLLs in each of the memory holes. In some cases, the tunneling layer 464 can comprise multiple layers such as in an oxide-nitride-oxide configuration.

FIG. 4E is a schematic diagram of a portion of the memory array 202. FIG. 4E shows physical data word lines WL0-WL111 running across the entire block. The structure of FIG. 4E corresponds to a portion 407 in Block 2 of FIG. 4A, including bit lines 411, 412, 413, 414, . . . 419. Within the physical block, in one embodiment, each bit line is connected to four NAND strings. Thus, FIG. 4E shows bit line 411 connected to four NAND strings NS0, NAND string NS1, NAND string NS2, and NAND string NS3.

FIG. 4E shows an example in which there are four drain side select lines in the physical block. For example, drain side select line SGD0 may be used to select SB0, drain side select line SGD1 may be used to select SB1, drain side select line SGD2 may be used to select SB2, and drain side select line SGD3 may be used to select SB3. Although only drain side select line SGD0 is depicted per SB, there may be more than one drain side select line per SB. Each set drain side select lines connects to a group of NAND strings in the SB.

Although the example memories of FIGS. 4-4E are three dimensional memory structure that includes vertical NAND strings with charge-trapping material, other 3D memory structures can also be used with the technology described herein.

The memory systems discussed above can be erased, programmed and read. In an embodiment, in-memory compute may be performed in the memory systems. At the end of a successful programming process, the threshold voltages of the memory cells should be within one or more distributions of threshold voltages for programmed memory cells or within a distribution of threshold voltages for erased memory cells, as appropriate.

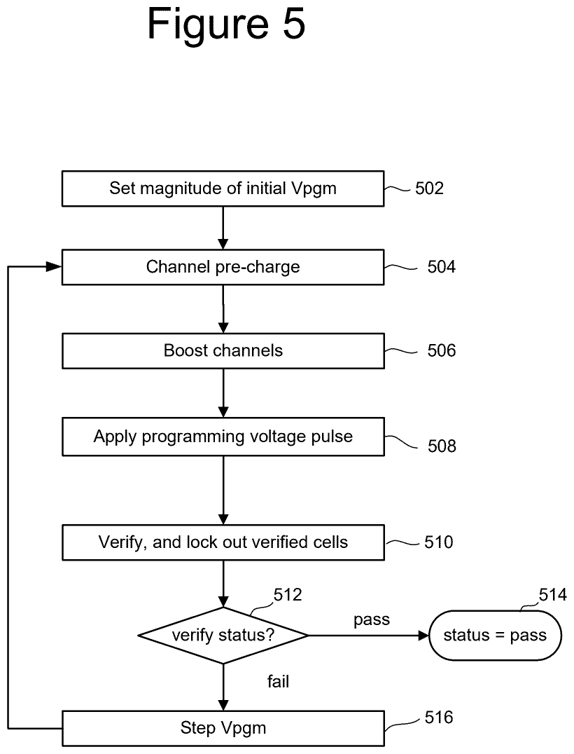

FIG. 5 is a flowchart describing one embodiment of a process for programming memory cells connected to a selected word line. Programming memory cells connected to a word line is referred to herein as programming the word line. For purposes of this document, the term program and programming are synonymous with write and writing. The process includes multiple loops, each of which includes a program phase and a verify phase. The process is used to program weights of an AI model into the memory cells. The weights may correspond to Vts, wherein a memory cell is programmed to a target Vt that represents the weight. In an embodiment, the process is used to program vectors of a vector database into the memory cells. The values of the elements of the vectors may correspond to Vts, wherein a memory cell is programmed to a target Vt that represents the values.

In one example embodiment, the process in FIG. 5 is performed for memory structure 202 using the one or more control circuits (e.g., system control logic 260, column control circuitry 210, row control circuitry 220) discussed above. Typically, the program voltage applied to the control gates (via a selected data word line) during a program operation is applied as a series of program pulses (e.g., voltage pulses). Between programming pulses are a set of verify pulses (e.g., voltage pulses) to perform verification. In many implementations, the magnitude of the program pulses is increased with each successive pulse by a predetermined step size. In step 502 of FIG. 5, the programming voltage signal (Vpgm) is initialized to the starting magnitude (e.g., ˜12-16V or another suitable level). Optionally a program counter PC may be maintained by state machine 262 and initialized at 1. In one embodiment, the group of memory cells selected to be programmed (referred to herein as the selected memory cells) are programmed concurrently and are all connected to the same word line (the selected word line). There will likely be other memory cells that are not selected for programming (unselected memory cells) that are also connected to the selected word line. That is, the selected word line will also be connected to memory cells that are supposed to be inhibited from programming. Additionally, as memory cells reach their intended target Vt, they will be inhibited from further programming. Those NAND strings (e.g., unselected NAND strings) that include memory cells connected to the selected word line that are to be inhibited from programming have their channels boosted to inhibit programming. When a channel has a boosted voltage, the voltage differential between the channel and the word line is not large enough to cause programming. To assist in the boosting, in step 504 the system will pre-charge channels of NAND strings that include memory cells connected to the selected word line that are to be inhibited from programming. In step 506, NAND strings that include memory cells connected to the selected word line that are to be inhibited from programming have their channels boosted to inhibit programming. Such NAND strings are referred to herein as “unselected NAND strings.” In one embodiment, at least some unselected word lines receive one or more boosting voltages (e.g., ˜7-11 volts) to perform boosting schemes. A program inhibit voltage is applied to the bit lines coupled the unselected NAND string.

In step 508, a program voltage pulse of the programming voltage signal Vpgm is applied to the selected word line (the word line selected for programming). If a memory cell on a NAND string should be programmed, then the corresponding bit line is biased at a program enable voltage. In step 508, the program pulse is concurrently applied to all memory cells connected to the selected word line so that all of the memory cells connected to the selected word line are programmed concurrently (unless they are inhibited from programming). That is, they are programmed at the same time or during overlapping times (both of which are considered concurrent). In this manner all of the memory cells connected to the selected word line will concurrently have their threshold voltage change, unless they are inhibited from programming.

In step 510, program verify is performed and memory cells that have reached their target states are locked out from further programming by the control die. Step 510 may include performing verification of programming by sensing at one or more verify reference levels. In one embodiment, the verification process is performed by testing whether the threshold voltages of the memory cells selected for programming have reached the appropriate verify reference voltage. In step 510, a memory cell may be locked out after the memory cell has been verified (by a test of the Vt) that the memory cell has reached its target Vt. For example, a memory cell may be locked out if it reaches a verify reference voltage. In an embodiment, when programming memory cells to states to represent values such as elements in vectors a memory cell may be locked out when it reaches the target state.

If, in step 512, it is determined that all of the memory cells have reached their target states (pass), the programming process is complete and successful because all selected memory cells were programmed and verified to their target states. A status of “PASS” is reported in step 514. Otherwise if, in step 512, it is determined that not all of the memory cells have reached their target states (fail), then the programming process continues to step 516.

At step 516 the programming voltage signal Vpgm is stepped up to the next magnitude. For example, the next pulse will have a magnitude greater than the previous pulse by a step size ΔVpgm (e.g., a step size of 0.1-1.0 volts). After step 516, the process loops back to step 504 and another program pulse is applied to the selected word line so that another iteration (steps 504-516) of the programming process of FIG. 5 is performed.

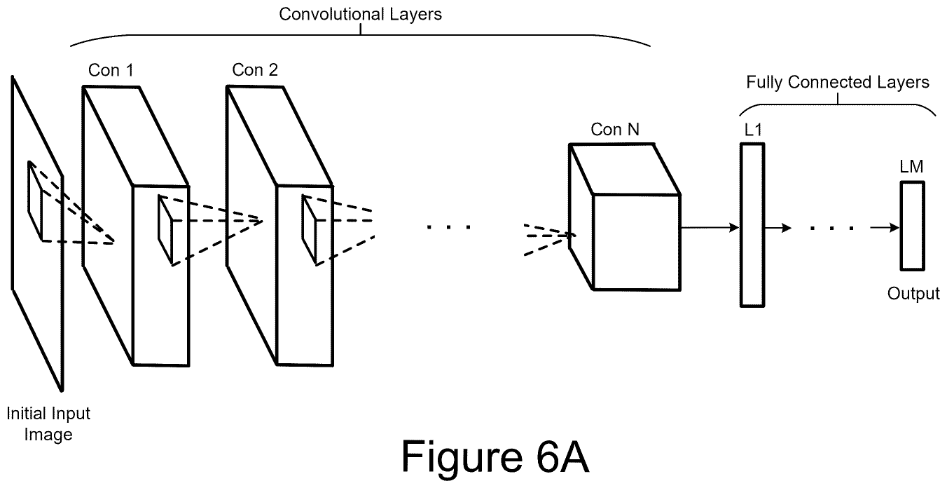

FIG. 6A is a schematic representation of an example of a convolutional neural network (CNN). FIG. 6A illustrates an initial input image of an array of pixel values, followed by a number of convolutional layers that are in turn followed by a number of fully connected layers, the last of which provides the output. Each neuron in the first convolutional layer (Con 1) takes as input data from an n x n pixel sub-region of the input image. The neuron's learned weights, which are collectively referred to as its convolution filter, determine the neuron's single-valued output in response to the input. In the convolutional layers, a neuron's filter is applied to the input image by sliding the input region along the image's x and y dimensions to generate the values of the convolutional layer. In practice, the equivalent convolution is normally implemented by statically identical copies of the neuron to different input regions. The process is repeated through each of the convolutional layers (Con1 to Con N) using each layer's learned weights, after which it is propagated through the fully connected layers (L1 to LM) using their learned weights.

FIG. 6B represents several fully connected layers of a neural network in more detail. In FIG. 6B the shown three layers of the artificial neural network are represented as an interconnected group of nodes or artificial neurons, represented by the circles, and a set of connections from the output of one artificial neuron to the input of another. The example shows three input nodes (I₁, I₂, I₃) and two output nodes (O₁, O₂), with an intermediate layer of four hidden or intermediate nodes (H₁, H₂, H₃, H₄). The nodes, or artificial neurons/synapses, of the artificial neural network are implemented by logic elements of a host or other processing system as a mathematical function that receives one or more inputs and sums them to produce an output. Usually each input is separately weighted and the sum is passed through the node's mathematical function to provide the node's output.

In common artificial neural network implementations, the signal at a connection between nodes (artificial neurons/synapses) is a real number, and the output of each artificial neuron is computed by some non-linear function of the sum of its inputs. Nodes and their connections typically have a weight that adjusts as a learning process proceeds. The weight increases or decreases the strength of the signal at a connection. Nodes may have a threshold such that the signal is only sent if the aggregate signal crosses that threshold. Typically, the nodes are aggregated into layers. Different layers may perform different kinds of transformations on their inputs. Signals travel from the first layer (the input layer), to the last layer (the output layer), possibly after traversing the layers multiple times. Although FIG. 6A shows only a single intermediate or hidden layer, a complex deep neural network (DNN) can have many such intermediate layers.

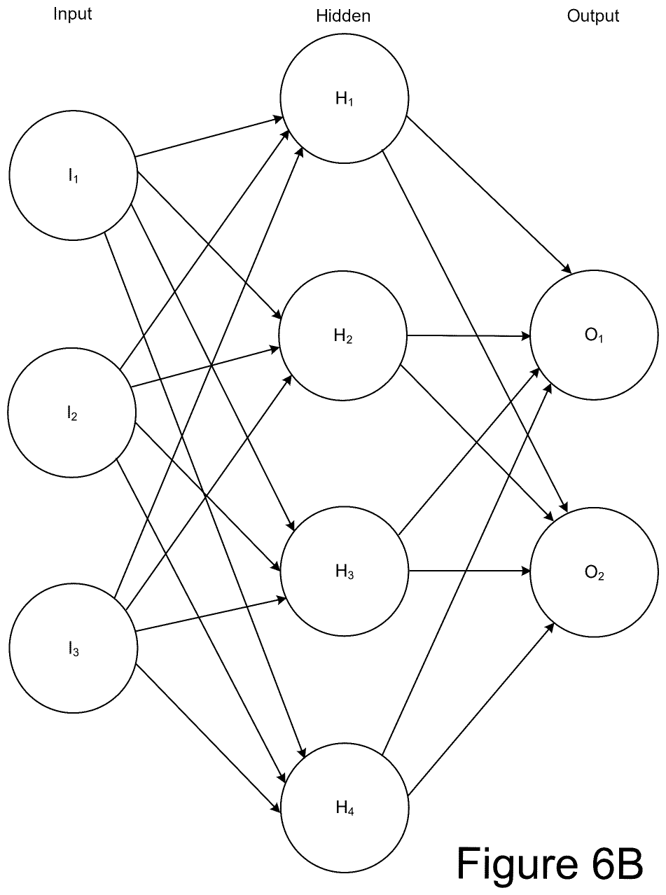

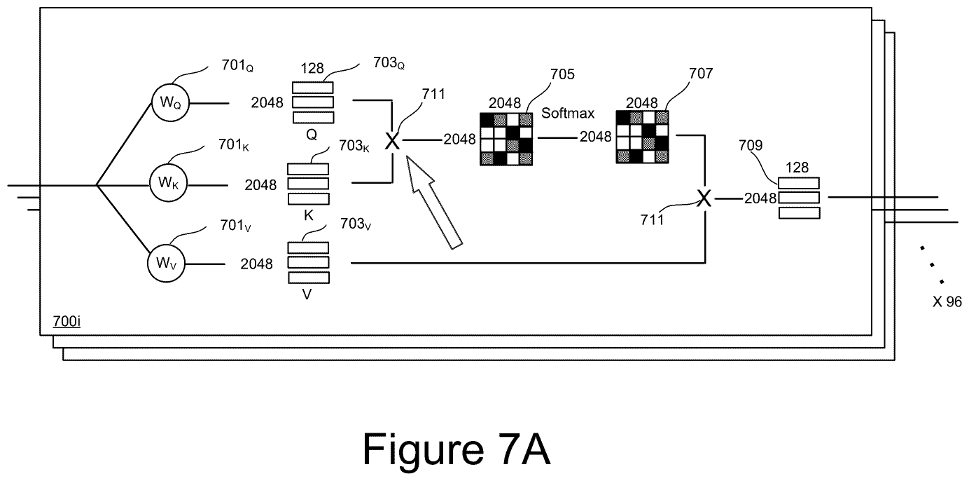

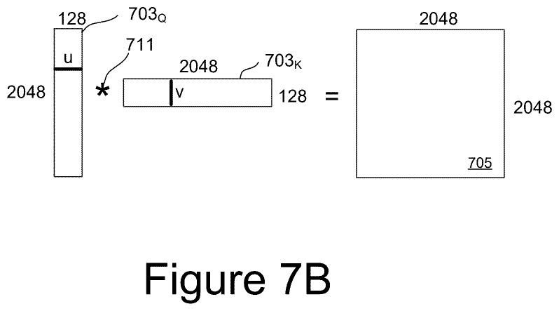

Embodiments of MAC disclosed herein may be used in a Large Language Model (LLM). Embodiments of MAC disclosed herein may be used in a Generative Pre-trained Transformer (GPT) models of deep neural networks. Some embodiments of MAC operations disclosed herein are used in a transformer model of a deep neural network. FIGS. 7A and 7B illustrate some elements of an example of a transformer model of a deep neural network. FIG. 7A shows some of the elements of a layer 700i of the transformer model, where there can be a large number of these layers, such 96 layers for example. The layer receives as inputs three sets of weights W_{Q} 701_{Q}, W_{K} 701_{K}, and W_{V} 701_{V}, corresponding to Query, Keys and Value matrices of weight values at 703_{Q}, 703_{K}, and 703_{V}. In this example the size of the matrices in 128×2048, which, as represented schematically, can be broken down into vectors. The Query and Key matrices are multiplied at 711 to generate the 2048×2048 matrix 705, where all of the sizes here are examples and other embodiments may have different sizes. Various neural network operations, such as Softmax, can be performed on the matrix 705 to generate the matrix 707. The output matrix 709 for the layer is then generated by a multiplication of matrices 707 and 703_{V}. FIG. 7B illustrates an embodiment of how the techniques disclosed herein can be applied to the matrix multiplications of FIG. 7A, such as multiplication 711 indicated by the arrow.

In FIG. 7A, the multiplication of Query, Keys and Value matrices involves values that change for each new computation. FIG. 7B illustrates the multiplication 711 of the Query matrix 703_{Q} and Keys matrix 703_{K}. The Query values are broken down into the u vectors and Keys values broken down into v vectors. The example size of 128 is smaller than the number of NAND word line layers, so that it fits the u vector. As the multiplication identity 1 or other matrix M is only programmed into the NAND array once with either 1 or 0 values, so that there is essentially no wear on the array.

A supervised artificial neural network is “trained” by supplying inputs and then checking and correcting the outputs. For example, a neural network that is trained to recognize dog breeds will process a set of images and calculate the probability that the dog in an image is a certain breed. A user can review the results and select which probabilities the network should display (above a certain threshold, etc.) and return the proposed label. Each mathematical manipulation as such is considered a layer, and complex neural networks have many layers. Due to the depth provided by a large number of intermediate or hidden layers, neural networks can model complex non-linear relationships as they are trained.

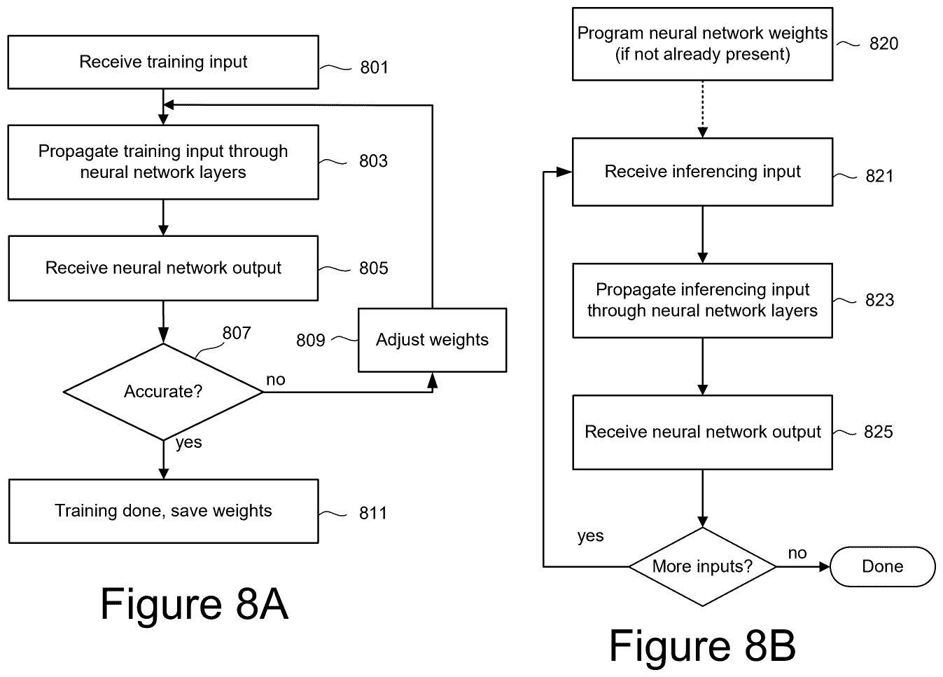

FIG. 8A is a flowchart describing one embodiment of a process for training a neural network to generate a set of weights. The training process is often performed in the cloud, allowing additional or more powerful processing to be accessed. At step 801, the input, such as a set of images, is received (e.g., the image input in FIG. 6A). At step 803 the input is propagated through the layers connecting the input to the next layer (e.g., CON1 in FIG. 6A) using the current filter, or set of weights. The neural network's output is then received at the next layer (e.g., CON2 in FIG. 6A) in step 805, so that the values received as output from one layer serve as the input to the next layer. The inputs from the first layer are propagated in this way through all of the intermediate or hidden layers until they reach the output. In the dog breed example of the preceding paragraph, the input would be the image data of a number of dogs, and the intermediate layers use the current weight values to calculate the probability that the dog in an image is a certain breed, with the proposed dog breed label returned at step 805. A user can then review the results at step 807 to select which probabilities the neural network should return and decide whether the current set of weights supply a sufficiently accurate labelling and, if so, the training is complete (step 811). If the result is not sufficiently accurate, the neural network adjusts the weights at step 809 based on the probabilities the user selected, followed by looping back to step 803 to run the input data again with the adjusted weights. Once the neural network's set of weights have been determined, they can be used to “inference,” which is the process of using the determined weights to generate an output result from data input into the neural network. Once the weights are determined at step 811, they can then be stored in non-volatile memory for later use, where the storage of these weights in non-volatile memory is discussed in further detail below.

FIG. 8B is a flowchart describing a process for the inference phase of supervised learning using a neural network to predict the “meaning” of the input data using an estimated accuracy. Depending on the case, the neural network may be inferenced both in the cloud and by an edge device's (e.g., smart phone, automobile process, hardware accelerator) processor. For example, a considerable portion of the computations of the inference phase may be performed by embodiments of in-memory compute. For example, memory system 100 may perform in-memory compute to perform VMM. In an embodiment, NAND memory is used for the in-memory compute. Step 820 includes programming neural network weights (if not already present). In an embodiment the neural network weights are programmed into NAND (e.g., 3D NAND). In one embodiment, the host 102 provides the weights to the memory controller 120, which instructs the system control logic 260 to program the neural network weights into storage 130 (e.g., 3D NAND). Note that the inference phase may be performed many times with these neural network weights. Therefore, in many cases the neural network weights will already be programmed when the inference phase begins.

At step 821, the input is received, such as the image of a dog in the example used above. As an example, the host 102 may receive the input. At step 823, the input data is then propagated through the neural network's layers. Step 823 will be similar to step 803 of FIG. 8A, but now using the weights established at the end of the training process at step 811. Step 823 may include performing in-memory compute to perform, for example, VMM. In an embodiment, the in-memory compute is performed in NAND memory. The memory controller 120 may provide results of the in-memory compute to the host 102. In an embodiment, the host 102 controls the propagation of the data through the neural network's layers. The host 102 may provide input vectors to the memory controller 120, with the memory controller 120 instructing the storage 130 to perform VMM. After propagating the input through the intermediate layers, the output is then provided at step 825.

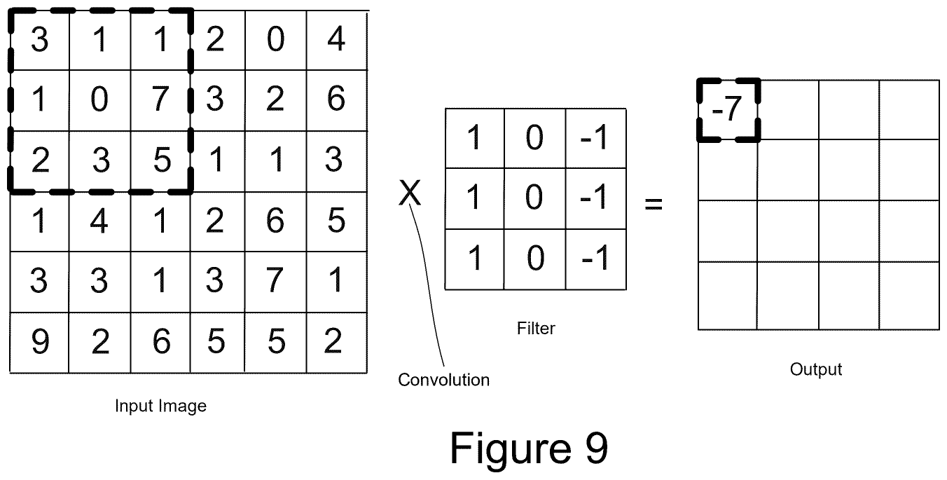

FIG. 9 is a schematic representation of a convolution operation between an input image and filter, or set of weights. In this example, the input image is a 6×6 array of pixel values and the filter is a 3×3 array of weights. The convolution operation is performed by a matrix multiplication of the 3×3 filter with 3×3 blocks of the input image. For example, the multiplication of the upper-left most 3×3 block of the image with the filter results in the top left value of the output matrix. The filter can then be slid across by one pixel on the image to generate the next entry of the output, and so on to generate a top row of 4 elements for the output. By repeating this by sliding the filter down a pixel at a time, the 4×4 output matrix is generated. Similar operations are performed for each of the layers. In a real CNN, the size of the data sets and the number of convolutions performed mean that extremely large numbers of such operations are performed involving very large amounts of data.

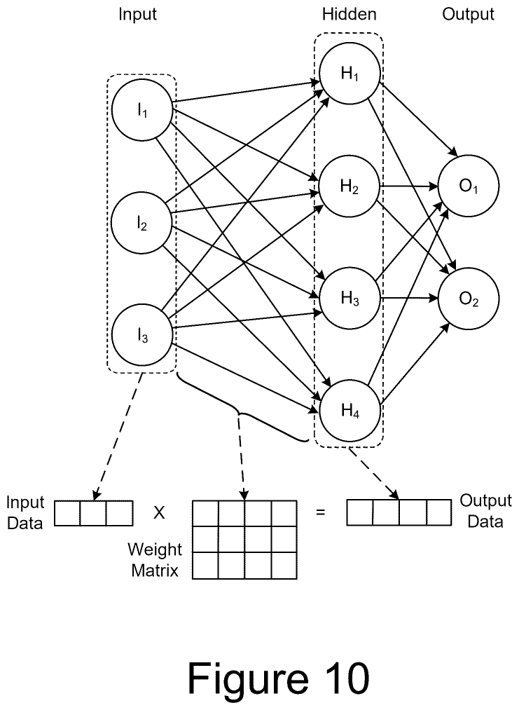

FIG. 10 is a schematic representation of the use of matrix multiplication in a fully connected layer of a neural network. Matrix multiplication, or MatMul, is a commonly used approach in both the training and inference phases for neural networks and is used in kernel methods for machine learning. FIG. 10 at the top is similar to FIG. 6B, where only a single hidden layer is shown between the input layer and the output layer. The input data is represented as a vector of a length corresponding to the number of input nodes. The weights are represented in a weight matrix, where the number of columns corresponds to the number of intermediate nodes in the hidden layer and the number of rows corresponds to the number of input nodes. The output is determined by a matrix multiplication of the input vector and the weight matrix, where each element of the output vector is a dot product of the vector of the input data with a column of the weight matrix.

A common technique for executing the matrix multiplications is by use of a multiplier-accumulator (MAC, or MAC unit). However, this has a number of issues. Referring back to FIG. 8B, the inference phase loads (or programs) the neural network weights at step 820 before the matrix multiplications are performed by the propagation at step 823. However, as the amount of data involved can be extremely large, use of a multiplier-accumulator for inferencing has several issues related to the loading of weights. One of these issues is high energy dissipation due to having to use large MAC arrays with the required bit-width. Another issue is high energy dissipation due to the limited size of MAC arrays, resulting in high data movement between logic and memory and an energy dissipation that can be much higher than used in the logic computations themselves.

To help avoid these limitations, the use of a multiplier-accumulator array can be replaced with other memory technologies. For example, the matrix multiplication can be computed within a memory array by leveraging the characteristics of NAND memory and Storage Class Memory (SCM), such as those based on ReRAM, PCM, FeRAM or MRAM based memory cells. This allows for the neural network inputs to be provided via read commands and the neural weights to be preloaded for inferencing. By use of in-memory computing, this can remove the need for logic to perform the matrix multiplication in the MAC array and the need to move data between the memory and the MAC array.

Inferencing in deep neural networks (DNNs) requires large amount of memory and computations, where the computations are usually real number multiplication and accumulations (MACs). Deep neural networks (DNNs), including large language models such as the transformer models are largely linear algebra engines built out of vector-matrix multipliers. Traditional DNNs are inferred on GPU devices, where the large size of DNN models require the GPUs to have a large memories and transfer large amounts of data, with a corresponding high cost. The process-in-memory techniques disclosed herein enable the computations to be implemented using the memory array. Although presented here primarily in the context of a 3D NAND memory, in other embodiments the non-volatile memory can be implemented in other memory technologies, such as ReRAM, MRAM, or PCM. A memory array will have a dynamic range (i.e., the max/min voltage/current it can represent) based on its design and the memory technology used, where a larger dynamic range has better precision and more tolerance to noise.

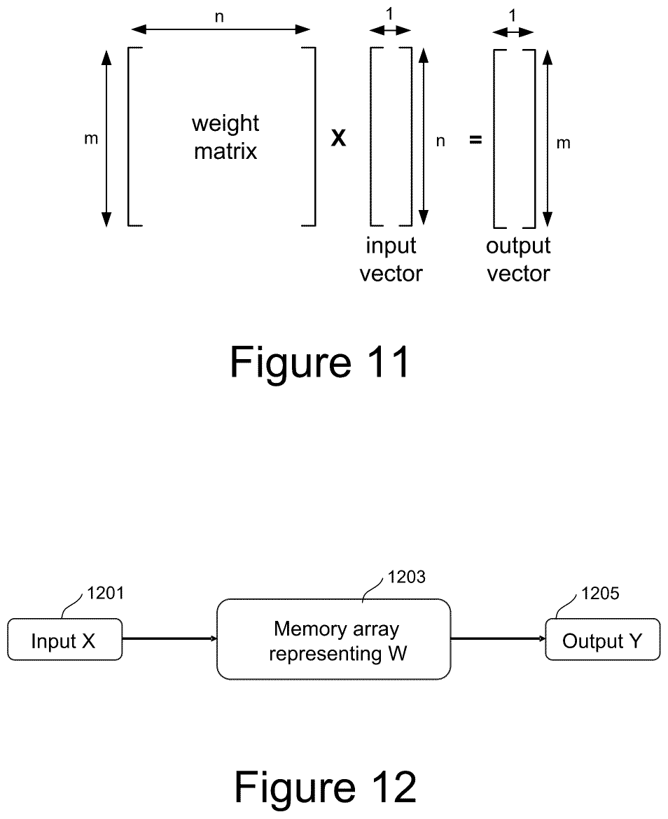

FIGS. 11 and 12 schematically illustrate vector-matrix multiplications, which are a basic computation unit of a DNN, and its implementation using a non-volatile memory array. More specifically, FIG. 11 illustrates the basic idea of a vector-matrix multiplication (VMM). The weight matrix is multiplied by an input vector to generate an output vector. If the input vector X is of size n×1 with components xᵢ, where i runs from 1 to n, and the weight matrix W is of size m×n with components Wⱼⁱ, where j runs from 1 to m, then the output vector Y is of size m×1 with components given by yⱼ=ΣᵢWⱼⁱxᵢ.

When implemented through an in-memory computation as illustrated in FIG. 12, the input X 1201 is applied to a set of weights W 1203 to programmed into a memory array to generate an output vector Y 1205. In an analog implementation, input vector X and output vector Y will be analog valued, with the weight values programmed as either analog values or multi-bit digital values. For example, in NAND memory devices multi-bit programming techniques are better developed so that weights might be written in a 6- or 8-bit per cell format, for example. In some embodiments, the weight matrix is programmed onto a basic CE, which allows the memory system to perform the VMM in parallel.

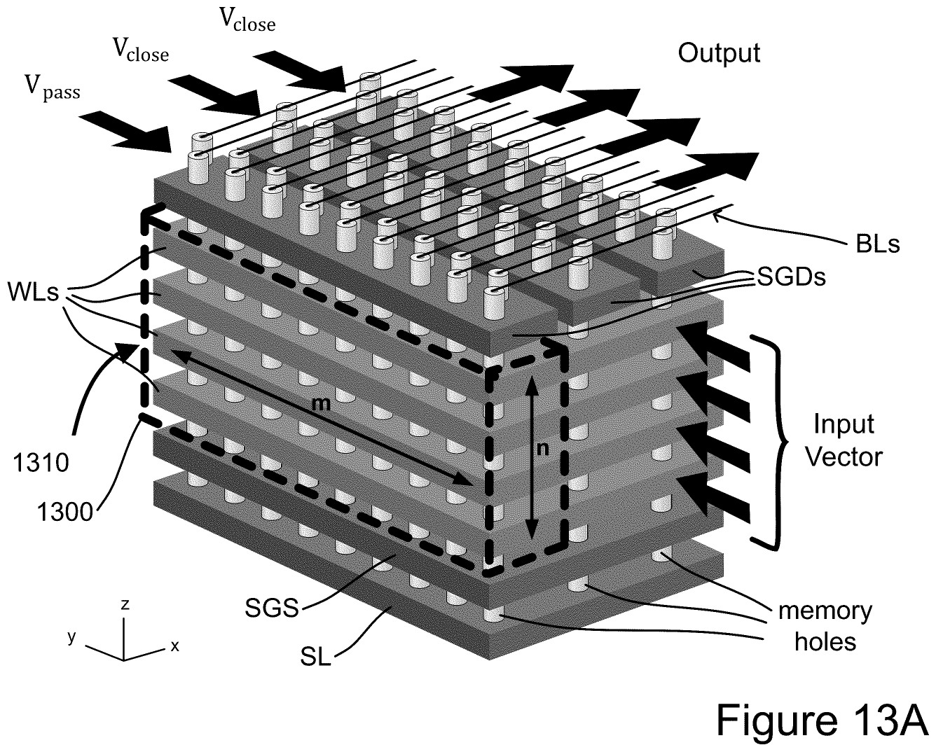

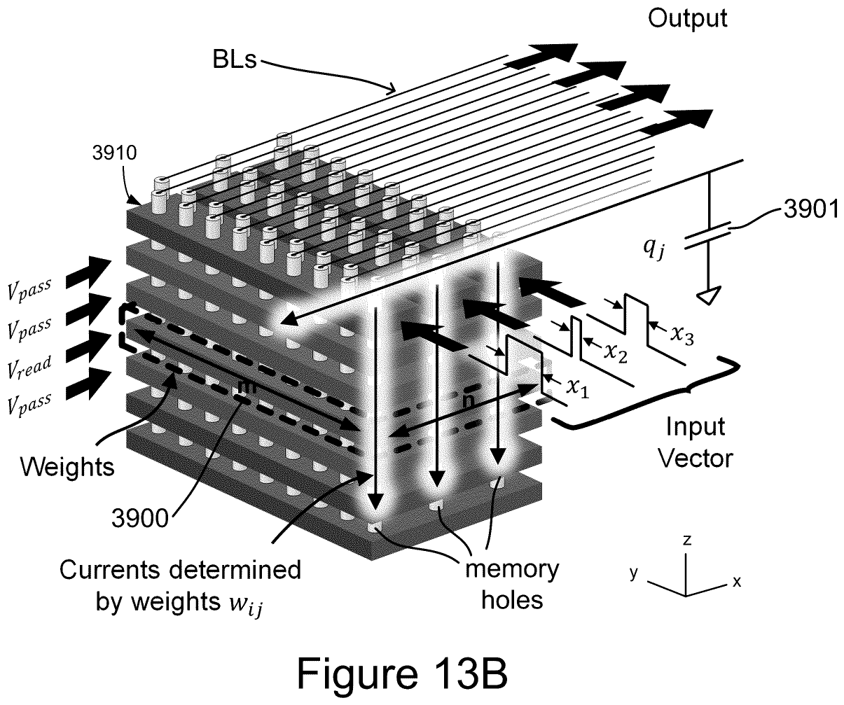

FIG. 13A illustrates an embodiment for the multiplication of a vector and a matrix using a 3D NAND structure in which the input vector is applied to the word lines. The matrix may be a weight matrix. Alternatively, a number of vectors from, for example, vector database may be programmed into the 3D NAND structure instead of the weight matrix. In this case, the input vector may be multiplied in parallel by each vector. In one aspect the parallel vector-vector multiplication is used in an ANN search.

FIG. 13A shows an abbreviated version of the 3D NAND structure presented above with respect to FIGS. 4-4E, showing four word lines WLs between a lower source side select gate SGS and three drain side select gates SGDs. At the bottom of the 3D NAND structure is a source line (SL). Each SGD may be used to select one sub-block with each sub-block containing a large number of NAND strings. There may be more or fewer than three SGDs per block. For example, FIGS. 4B and 4E depict an example with four SGDs per block. The portion of the 3D NAND structure shown in FIG. 13A may reside within one block. The memory holes run vertically through the horizontal layers and are each connected to a corresponding bit line BL through drain side select gates (SGD). To select a sub-block 1300, the corresponding drain side select gate SGD is biased at Vₚₐₛₛ to turn these gates on, while for the other, non-selected blocks, the SGDs are biased at the off voltage of V_{close}. Note that each bit line connects to one memory hole (NAND string) in each sub-block.

Dashed lines highlight an embodiment of a basic CE 1310, which in this embodiment corresponds to a sub-block 1300. The basic CE may be used for VMM or parallel vector-vector multiplication. The basic CE 1310 has a kernel size of m×n. The term “kernel” is being used in this context to refer to the fundamental size for computation. The term “m” refers to the number of parallel operations that may be performed using the basic CE 1310. For example, the basic CE 1310 may be used to multiply, in parallel, an input vector by “m” vectors programmed into the basic CE 1310. The term “n” refers to the size or number of the elements (e.g., vectors, weights) that are involved in each of these parallel multiplications. For example, each vector may have up to “n” elements. The WLs to which the signals for the input vector are applied may also be considered to be a part of the basic CE. In this example, the word lines are shared by multiple basic CEs.

An example of using the basic CE for VMM will now be discussed. To realize the multiplication of the input vector and a matrix (e.g., a set of weights for a neural network), the matrix values (e.g., weights) are programmed into memory cells in a basic CE 1310, such as sub-block 1300. Programming a weight into a NAND memory cell means that the memory cell is programmed to a target state (e.g., Vts, currents) that represents the weight. An embodiment of the memory system 100 converts the weights to Vts. The memory system 100 may store a table that maps from the weights to the Vts. Alternatively, the memory system 100 may perform a calculation to map from the weights to the Vts. An embodiment of the memory system 100 converts the weights to currents (with the assumption of default voltages applied to the memory cell). For example, the memory system 100 may assume default voltages applied to the selected word line, the source line, and the drain end of the NAND string. The memory system 100 may store a table that maps from the weights to the target currents. Alternatively, the memory system 100 may perform a calculation to map from the weights to the target currents.

FIG. 13A shows how the memory cells in sub-block 1300 may be programmed to represent an m×n matrix. With some techniques one entry in the weight matrix is represented in a group of two or more cells. In one technique the one entry in the weight matrix is represented by two cells on a first NAND string and two cells on a second NAND string. Thus, the m and n in FIG. 13A refer to the entries in the weight matrix, which is not necessarily the same as the number of cells that are programmed to represent the weight matrix. As one example, n may be a few hundred and m may be about 64K. FIG. 13A shows a simplified example with only four cells on each NAND string, but typically there will be many more memory cells on each NAND string. For example, 3D NAND memory can be fabricated to have more than 100 NAND memory cells on a NAND string. It is not required that all memory cells on the NAND string be used to store the weights. FIG. 13A shows 18 NAND strings in the depicted portion of sub-block 1300; however, 3D NAND memory can be fabricated with thousands of NAND strings in a sub-block. As an example, m may be 64K. In one implementation, m NAND strings may be used for the m dimension. In one implementation, 2*m NAND strings may be used for the m dimension. 3D NAND memory can be fabricated to have at least 128K NAND strings in a sub-block. The weights, or other matrix entries, are static and are changed rarely (if at all) in order not to compromise endurance of the NAND memory. The drain side select gate for the selected sub-block (1300 in this example) receives the select gate on voltage Vₚₐₛₛ, while the drain side select gates for unselected blocks are biased at select gate off, or non-select voltage, V_{close}. The input vector, which is dynamic and can change for every new operation, is applied on the word lines of the block. In an embodiment, the memory system 100 converts the values in the input vector to voltages to apply to the word lines. The output vector, corresponding to the product of the input vector and the stored matrix, is then determined based on the signals (e.g., current) on the bit lines. In one technique the difference in current between two bit lines is used to determine a dot product of the input vector and a column of the weight matrix.

The basic CE 1310 may also be used for parallel vector-vector multiplication. In one embodiment, vectors of a vector data base are programmed into the basic CE 1310 similar to how the weights of the weight matrix may be programmed into the basic CE 1310. In an embodiment the memory system forms tree leaves such that each tree leaf has no more than “m” vectors, wherein all of the vectors of a tree leaf can be programmed into the basic CE 1310. If the vectors have a dimension of no more than “n,” then the entire vector can fit within the basic CE 1310. If the vectors have a dimension of more than “n,” then each vector can be split into two or more sub-vectors each having a dimension of no more than “n,” wherein each sub-vector will fit within a basic CE 1310. Further details of embodiments of the mapping of the vectors to the basic CEs are discussed below. The multiplication for parallel vector-vector multiplication may be similar to the VMM. The memory system may apply the input vector to the word lines and sense the bit lines, as described above. In an embodiment the memory system determines a distance between the input vector and each respective vector in the basic CE 1310 based on the respective bit line currents.

FIG. 13B illustrates a timing based method for in-memory compute. The method may be used for analog values matrix-vector multiplication. The method may be used for parallel multiplication of the input vector by vectors programmed in the memory cells. In this example, the input vector is applied to the SGD lines. For VMM, the set of weights are programmed into the NAND memory cells. For parallel vector-vector multiply, vectors from a vector data base are programmed into the NAND memory cells. The output is provided on the bit lines, with the output value for a bit line q saved as accumulated charge qⱼ on the capacitor 3901. In this example the analog values of the input vector are encoded as the duration of a high voltage level. FIG. 13B shows three examples of timing-based inputs, x₁>x₃>x₂, where the duration is proportional to the amplitude of the analog value. In FIG. 13B only three SGD lines are depicted, but there may be many more SGD lines to allow for a larger input vector.

In FIG. 13B, the basic CE 3900 includes memory cells connected to a word line layer in an x-y plane. Therefore, the basic CE 3900 is oriented in a different direction than the basic CE in FIG. 13A. The drain side select lines 3910 to which the signals for the input vector are applied may also be considered to be a part of the basic CE. In this case, the drain side select lines 3910 may be shared by different basic CEs. The architecture in FIG. 13B allows for a great deal of flexibility in selecting the size of the “n” dimension (e.g., size of input vector). As one example, there may be six SGD lines in each block. The basic CE may span multiple blocks to allow for a much larger input vector. As one example, the input vector has a dimension of 1536. By selecting 256 blocks in the plane, each with six SGDs 3910, an input vector of dimension of 1536 may be realized.

In embodiments of FIGS. 13A and 13B a basic CE is associated with the bit lines in the plane to allow for parallel computation. However, note that the bit lines in the plane may be shared with different CEs such that the memory system typically selects on CE in a plane at time.

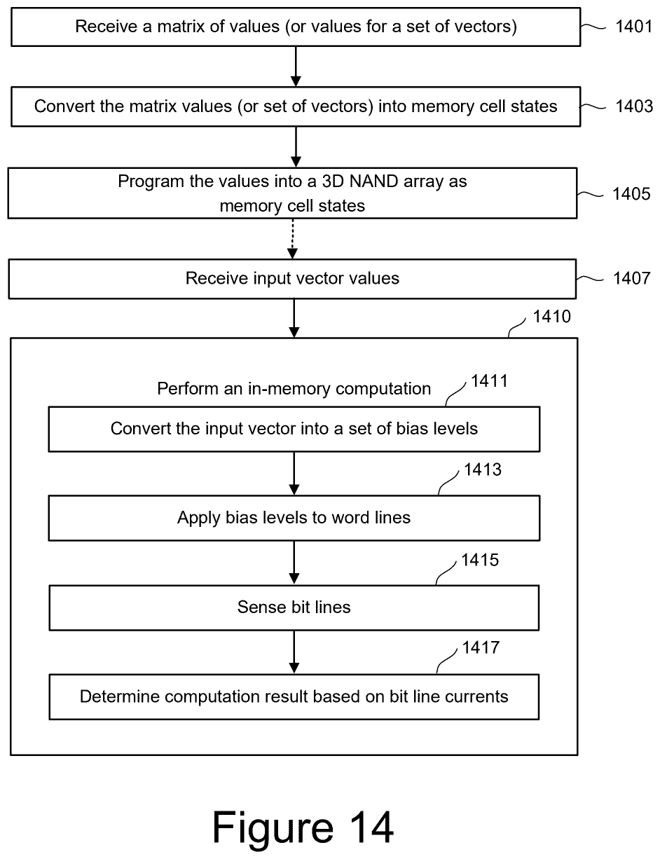

FIG. 14 is a flowchart for an embodiment of operating a 3D NAND multiply and accumulate engine. In one aspect, the process may be used to multiply an input vector by a matrix that is programming into NAND the memory cells. In another aspect, the process may be used to multiply an input vector by a set of vectors that are programming into NAND the memory cells. The process may be performed by a combination of memory controller 120 and/or control circuitry (e.g., system control logic 260, column control circuity 210, row control circuity 220) of memory die 200 or control die 211. Beginning at step 1401, either a matrix of values or a set of vectors is received. The matrix (or set of vectors) is received, for example, at the memory controller 120 from the host 102. At step 1403, the matrix values matrix (or values of the set of vectors) are converted to memory cell states for NAND memory cells. An embodiment of the memory controller 120 converts the values to Vts. The memory system 100 may store a table that maps from the values to the Vts. Alternatively, the memory controller 120 may perform a calculation to map from the values to the Vts. In one embodiment, the system control logic 260 converts the values to Vts. An embodiment of the memory controller 120 converts the values to memory cell currents. The memory system 100 may store a table that maps from the values to the memory cell currents. Alternatively, the memory controller 120 may perform a calculation to map from the values to the memory cell currents. In one embodiment, the system control logic 260 converts the values to memory cell currents.

At step 1405 the values are programmed into the 3D memory array as memory cell states. The programming may be performed by the control circuitry of memory die 200 or control die 211 in response to an instruction from the memory controller 120. Thus, the memory die control circuitry can then program the values into the memory array 202 in step 1405. In some embodiments, the values can be pre-programed into the memory array before the memory device shipped to the user.

At step 1407 input vectors are received. In an embodiment, the memory controller 120 receives the input vectors from the host 102. The in-memory multiplication (e.g., VMM, vector-vector multiply, MAC) is then performed for an input vector and the values that were programmed into the NAND memory cells at step 1410. In one embodiment, the technique depicted in FIG. 13A is used in step 1410. In step 1411 the input vector (x) is converted into a set of bias levels. In one embodiment, the memory controller 120 converts the input vector to bias levels. In one embodiment, the system control logic 260 and/or row decoder 222 converts the input vector values into a corresponding set of bias levels. At step 1413 the bias levels are applied by the array drivers 224 to the word lines. Also in step 1413, a voltage is applied to the SGD of the selected sub-block to turn on this “selected SGD” and a voltage is applied to the SGDs of the unselected sub-block to turn off the “unselected SGDs”. Thus, the NAND channels in the selected sub-block are connected to the bit lines, whereas the NAND channels in the unselected sub-block are cut off from the bit lines Furthermore, the source line may be grounded and the SGS in the selected block has a voltage applied thereto to turn on this SGS to connect the NAND channels to the source line. Additionally, a bit line sensing voltage is applied to the bit lines. An example magnitude for the bit line sensing voltage is about 1.0V as applied to bit line. At step 1415 the bit line currents are sensed. At step 1417 a computation result is determined based on the bit line currents.

In the case of Vector-Matrix Multipliers (VMMs), such as when a matrix of values (e.g., weight of a neural network) are programmed into the memory cells of a memory array, the weights can be programmed as analog or multi-bit (e.g., 6- or 8-bit) values. The inputs may then be applied as analog voltage level vertical input vectors on word lines (as in FIG. 13A). Alternatively, the inputs may then be applied on the SGD lines (as in FIG. 13B). Thus, step 1410 in FIG. 14 may be modified to perform a technique depicted in FIG. 13B. In this case, step 1411 may be modified to convert the input vector to timing signals, which are applied to the SGD lines in step 1413.

In some embodiments in-memory techniques for parallel vector-vector multiplication are used in approximate nearest neighbor (ANN) searches. ANNOY (Approximate Nearest Neighbors Oh Yeah) is an example of an ANN. The ANN may be a tree based search in which one or more trees are formed with each tree containing intermediate nodes and leaf nodes. The leaf nodes may be populated with vectors from a vector database. A commonly used tree search technique for approximate nearest neighbor searching when all of data can be loaded to memory are ANNOY search algorithms. These can be fast and accurate for real-world data and serve as a building block for database with billions of elements. Thus, they are used in many such search algorithms. To improve the efficiency of tree based searches such as ANNOY, embodiments below program the vectors of a database into basic CEs allowing distances between vectors to be determined through compute-in-memory multiplications, resulting in a Log(N) search complexity.

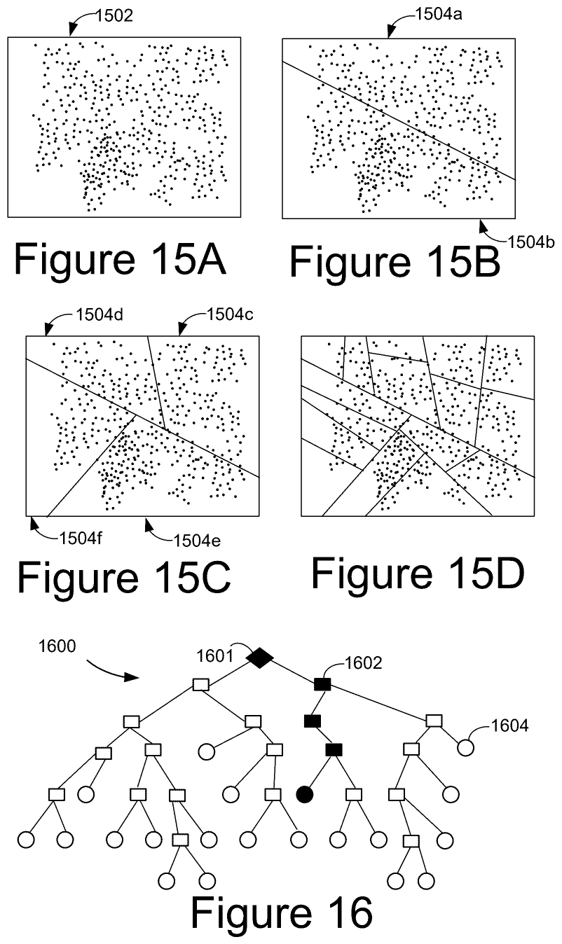

FIG. 15A-15D are diagrams showing a general overview of ANNOY. In this example, ANNOY has a 2-means tree. ANNOY may have multiple trees. ANNOY may have a priority queue. FIG. 15A shows a space 1502 having a number of data points, wherein each data point is represented by a “dot” or “point”. For ease of illustration and discussion, the space 1502 is depicted as two dimensional and the following discussion provides two-dimensional examples. However, more generally higher dimensions may be used. The space 1502 is repeatedly divided into smaller and smaller cells. FIG. 15B shows the space divided into two cells 1504a, 1504b. The division may be made by selecting two locations at random and forming a line from those two locations. FIG. 15C shows a further division in which cell 1504a have been divided into cells 1504c and 1504d. Also, cell 1504b has been divided into cells 1504e and 1504f. In an embodiment, after the space has been divided as far as desired each cell will correspond to leaf of a tree. Also, each cell may contain a number of data points. In an embodiment, a vector is programmed into the NAND memory cells for each data point. FIG. 15D shows the spaces after still more division. In an embodiment, the space 1502 is divided until the cells have a suitable size for mapping the cells to the basic CEs. In an embodiment, the cells have a size to take advantage of the parallelism of the in-memory compute using basic CEs. Moreover, the size of the cells may be controlled to efficiently use a high percentage of the NAND memory cells in a basic CE.

A search may be performed by selecting one of the cells in which the query (e.g., input vector) lives. The search may include determining a distance between the input vector and the vectors in the cell. In an embodiment, in-memory compute is used to multiply the input vector by each vector in the cell. A distance between the input vector and each respective vector in the cells is determined based on the vector-vector multiplications. The ability to perform a large number of vector-vector multiplications in parallel using the basic CEs in NAND memory results in a very fast search for the vector that is closest to the input vector.

FIG. 16 depicts a simplified example tree that may be used in an ANN. The tree has a root node 1601 (diamond), a number of intermediate nodes 1602 (rectangles) and number of leaf nodes 1604 (circles). The intermediate nodes 1602 may be hyperplanes. As one example, the hyperplanes may be described by the lines in, for example, FIG. 15B-15D. In an embodiment, metadata about the tree 1600 is stored into the NAND memory system. The metadata for the intermediate nodes 1602 pertains to information about the hyperplane used for splitting the data points. In an embodiment, the metadata for the leaf nodes 1604 contains indices of the data points that fall within the region of space 1502 covered by the leaf node 1604. In one embodiment, the tree structure is stored into pages of NAND memory cell. A page of NAND memory cells refers to a basic unit of programming or reading NAND memory. The nodes of the tree may be serialized to a contiguous region of memory, which can be mapped to memory pages. The serialized data may be organized in pages in order to ensure that the nodes are aligned to page boundaries. In many cases, multiple nodes may be loaded with reading a single page, which significantly reduced access of the NAND storage.

A search may be performed by starting at the root node 1601 and traversing intermediate nodes 1602 until reaching a leaf node 1604. An example search path is depicted by the black nodes in the tree 1600. Once the leaf node 1604 is located, vector-vector multiply is performed. The vector-vector multiply multiplies an input vector by each of the vectors of the leaf node 1604. In the example in FIG. 16 the tree is a binary tree. However, more generally the tree(s) used in embodiments of ANN is not required to be a binary tree.

In some embodiments, the memory system forms multiple trees 1600. These trees may be formed from the same space of data points (see 1502 in FIG. 15A). The division of the space 1502 into the hyperplanes may be performed randomly such that each tree will be different. The accuracy of the ANN may be improved by searching based on multiple such trees. Moreover, the ANN can be performed on multiple such trees in parallel. Therefore, accuracy can be increased without sacrificing speed in the vector-vector multiplications.

In an embodiment, a priority queue is used when searching with multiple trees. The ANN based on a first tree may generate a first set of top (nearest) points. The ANN based on a first tree may generate a second set of top (nearest) points. The worst results from the first set are then replaced with the best results from the second set. This may be repeated for other trees. This process can be performed extremely efficiently using embodiments of in-memory compute by performing the in-memory compute for many trees in parallel.

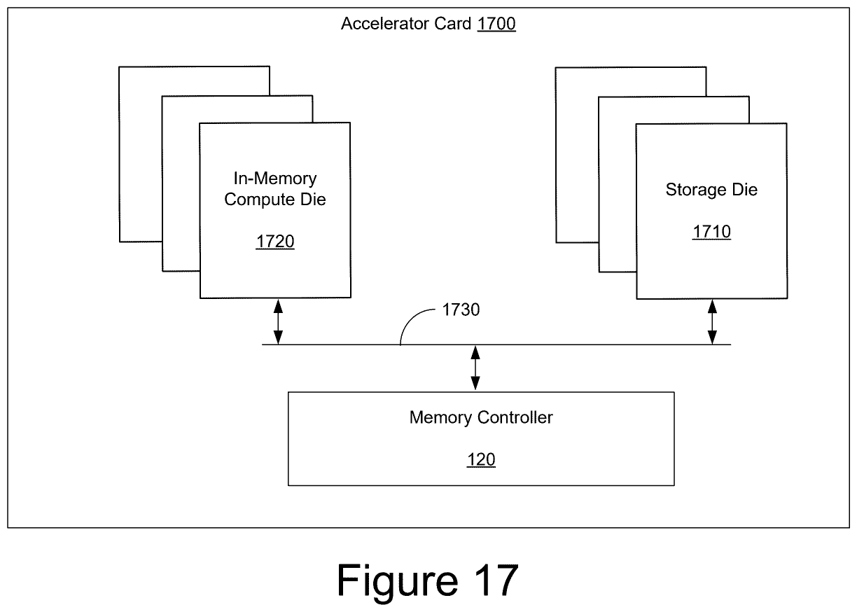

FIG. 17 depicts one embodiment of an accelerator card 1700 that may be used for ANN. The accelerator card 1700 has a memory controller 120, a number of storage dies 1710 and a number of in-memory compute dies 1720. In an embodiment, the storage dies 1710 are used to store a vector database and metadata associated with the vector database. The storage dies 1710 may be used to store the information about the trees 1600 described above. The memory controller 120 may read from the storage dies 1710 to traverse the tree(s) 1600 until one or more candidate leaf nodes are located. In an embodiment, the in-memory compute dies 1720 are used to perform in-memory computation, such as MAC, vector-vector multiply, VMM, etc. Each in-memory computation die 1720 may contain a significant number of basic CEs. Moreover, each in-memory computation die 1720 may contain a number of planes, with each plane capable of performing an in-memory compute at the same time.

Each storage die 1710 and each in-memory compute die 1720 may, for example, be implemented with a memory die 200 (see FIG. 2A) or an integrated memory assembly 207 (see FIG. 2B), but is not limited thereto. Optionally, a single die can be used for both storage die and an in-memory compute die. The memory controller 120 communicates with both the storage dies 1710 and the in-memory compute dies 170 over bus 1730. The bus 1730 may be an ONFI bus, but is not limited thereto. The accelerator card 1700 is one embodiment of the storage system 100 of FIG. 1. Further details of an embodiment of a memory controller 120 are discussed in connection with the storage system 100 of FIG. 1.

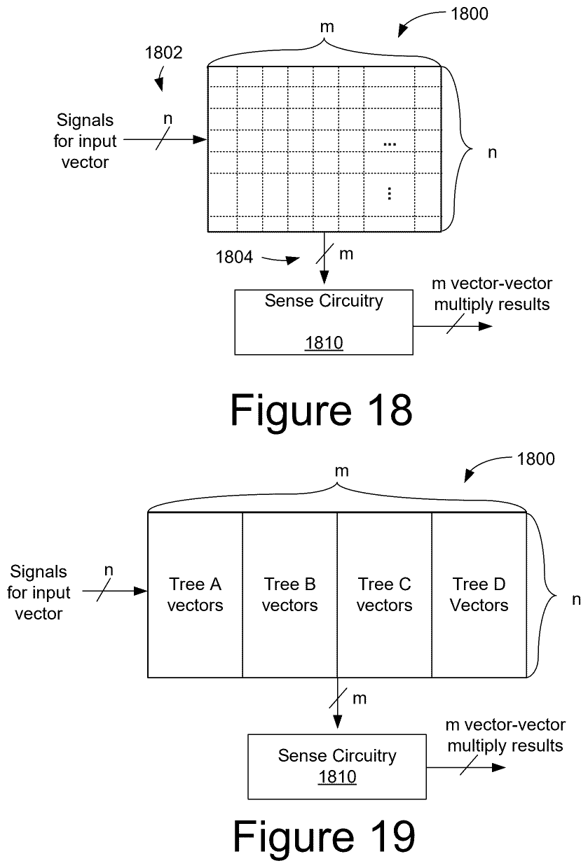

FIG. 18 depicts a basic compute engine (CE) in NAND that may be used to perform parallel vector-vector multiplication. The parallel vector-vector multiplication may be used to determine a distance between an input vector and vectors of a leaf node of a tree. The basic CE 1800 includes a number of NAND memory cells. The basic CE 1800 has a kernel size of m×n. The basic CE 1800 has an input 1802, which can receive up to n signals in parallel. The basic CE 1800 has an output 1804, which can output up to m signals in parallel. Examples of NAND memory structures that may be used to implement the basic CE 1800 are depicted in FIGS. 13A and 13B. The memory system programs vectors into the basic CE 1800. In an embodiment, up to m vectors may be programmed into the basic CE 1800. In one embodiment, each vector may have a dimension of up to n elements. Some embodiments allow for vectors having a dimension greater than n by splitting the vector into sub-vectors and programming each sub-vectors into a different basic CE 1800.

The memory system generates signals to represent the input vector and applies those signals to the basic CE. FIGS. 13A and 13B shows two examples of applying signals that represent an input vector to the basic CE. In the examples, there may be up to n signals. The sense circuitry 1810 senses the basic CE 1800. FIGS. 13A and 13B shows two examples in which the bit lines may be sensed. In this example, up to m output signals may be sensed from the basic CE 1800 in parallel. The sense circuitry 1810 outputs m vector-vector multiply results. The memory system may determine a distance between the input vector and each respective vector stored in the basic CE 1800 based on the multiplication results.

In some embodiments, a basic CE 1800 is programmed with the vectors of a single leaf node. In this case, the leaf node may have up to m vectors. However, the basic CE 1800 can be programmed with vectors from different leaf nodes. In one embodiment, a basic CE 1800 is programmed with vectors from leaf nodes from different trees. FIG. 19 shows an example in which the basic CE 1800 is programmed with vectors from leaf nodes from different trees. The basic CE 1800 in FIG. 19 is similar to the one in FIG. 18 in that it has an m×n kernel. In the example in FIG. 19, vectors from a leaf node in Tree A, vectors from a leaf node in Tree B, vectors from a leaf node in Tree C, and vectors from a leaf node in Tree D are programmed into the basic CE. The different trees may be formed from the same space of data points, but formed differently as discussed above. For example, the hyperplanes or the like may be generated randomly. The parallel vector-vector multiplication is similar to the example in FIG. 18. A total of m vector-vector multiplications may be performed in parallel.

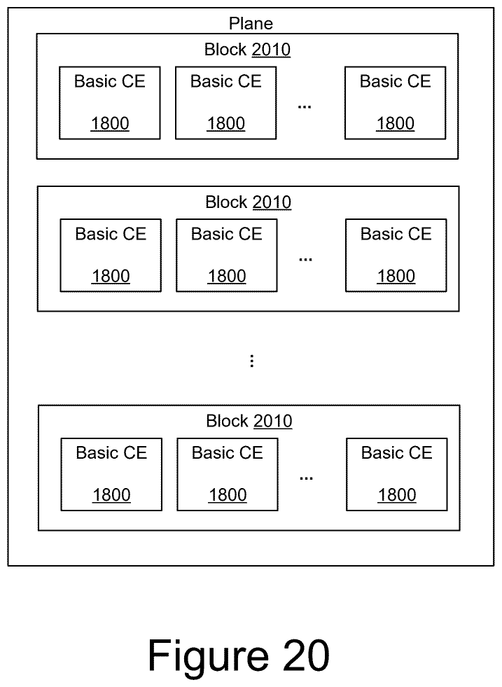

FIG. 20 is a block level diagram showing one example of how a plane may contain many basic CEs 1800. Each block contains many NAND strings and a number of word lines. In this embodiment, each block 2010 has a number of basic CEs 1800. In this example, the NAND memory cells for a basic CE 1800 are within the same block. However, the bit lines associated with a basic CE may be shared among the blocks. In one embodiment, the memory system selects a single basic CE in a plane for an in-memory compute. However, for additional parallelism, the memory system may select basic CEs is different planes.

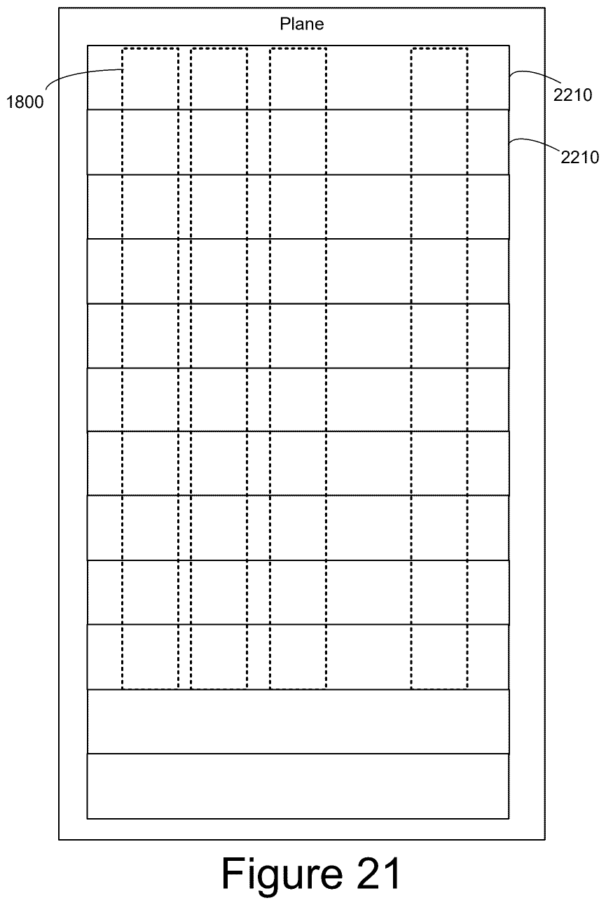

FIG. 21 is a block level diagram showing another example of how a plane may contain many basic CEs 1800. In this embodiment, the plane contains a number of blocks. Each block contains many NAND strings and a number of word lines. The basic CEs 1800 are indicated by dashed lines. Each basic CEs 1800 contains memory cells from a number of blocks. In one embodiment, the basic CU 3900 depicted in FIG. 13B is used. The architecture in FIG. 21 allows the n dimension to be selectable based on the size of the input vector. It is not required that all blocks in the plane be used. In one embodiment, the memory system selects a single basic CE in a plane for an in-memory compute. However, for additional parallelism, the memory system may select basic CEs is different planes. The organizations of the basic CEs in FIGS. 20 and 21 can be combined, wherein for example, the unused blocks in FIG. 21 could contain basic CEs as in FIG. 20.

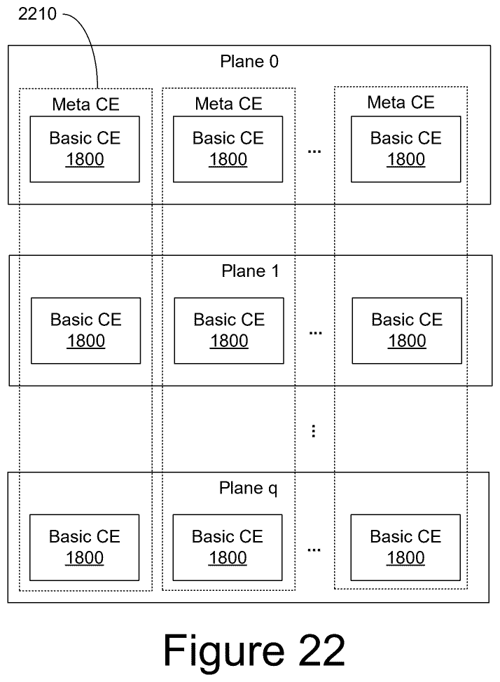

As noted above, a massive amount of parallelism in vector-vector computation may be achieved by performing in-memory compute in different planes in parallel. FIG. 22 shows an embodiment having meta CEs. A number of planes are depicted (Plane 0, Plane 1, Plane q). Each plane has a number of basic CEs 1800. The basic CEs 1800 could be, but are not limited to those depicted in FIGS. 13A, 13B, 20, or 21. A meta CE 2210 contains a basic CE 1800 from each of a number of planes. In general, a meta CE 2210 contains a basic CE 1800 from each of two or more planes. In an embodiment, the memory system performs a vector search in parallel using a meta CE 2210. As one example, a memory die may have 64 planes. If, for example, each basic CE 1800 is capable of 400 parallel vector-vector multiplies, then about 25,600 vector-vector multiplies may be performed in parallel. Thus, the memory system could compute about 25,600 vector distances based on these multiplies. Moreover, the parallel vector-vector multiplies may be performed very quickly. For example, it may take only about 16 microseconds to perform the parallel vector-vector multiplies. Thus, an ANN search may be performed very quickly.

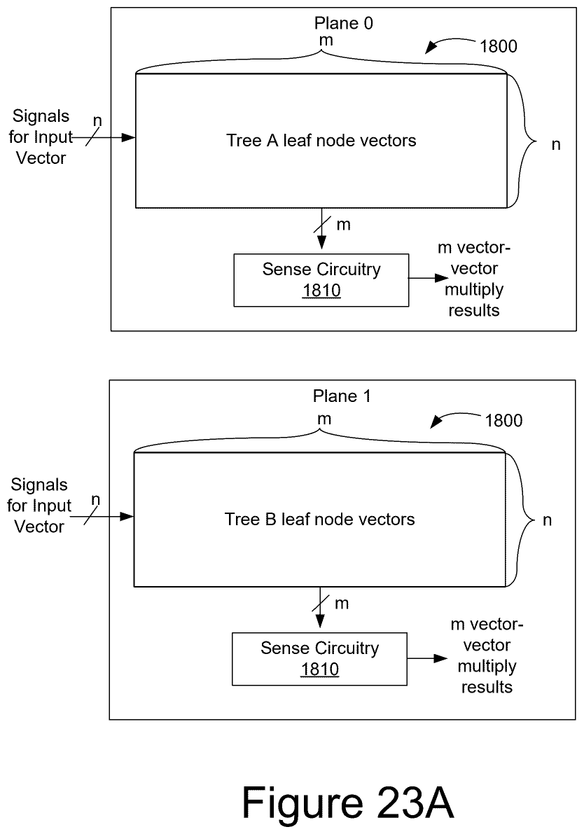

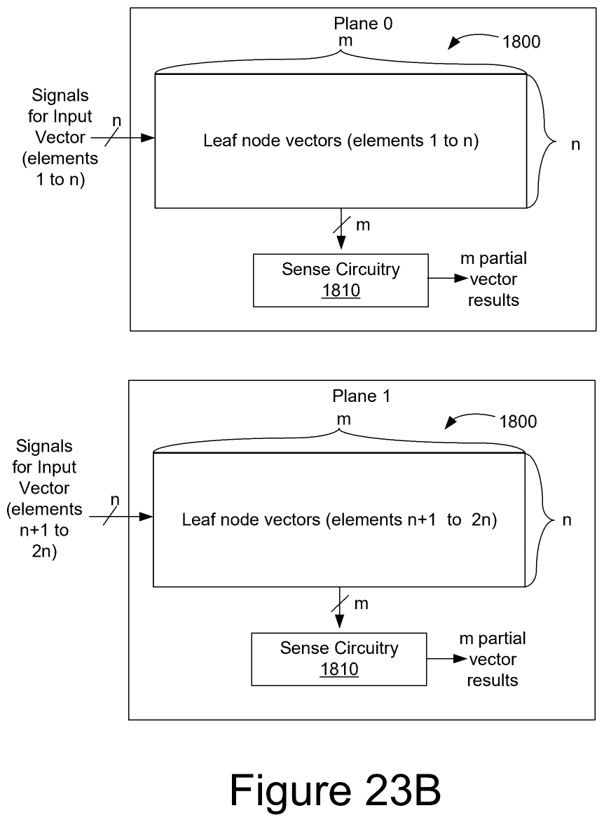

FIG. 23A shows an embodiment of a technique for in-memory compute of vectors, which may be used to calculate distances between vectors. A basic CE 1800 in Plane 0 is programmed with vectors from a leaf node of Tree A. A basic CE 1800 in Plane 1 is programmed with vectors from a leaf node of Tree B. Many other basic CE 1800 will also be programmed, but those are not depicted in FIG. 23A. The memory system computes a distance between an input vector and the vectors of the leaf node in Tree A and the vectors of the leaf node in Tree B in parallel. The signals for the input vector are applied to the basic CE 1800 in Plane 1 at substantially the same time as applying the signals for the input vector to the basic CE 1800 in Plane 0. The sense circuitry 1810 on plane 0 senses the signals on the bit lines connected to the basic CE 1800 in Plane 0 at substantially the same time as the sense circuitry 1810 on plane 1 senses the signals on the bit lines connected to the basic CE 1800 in Plane 1. This concept may be extended to many more planes, wherein a massive amount of parallel computation can be performed. As with other examples described herein, Tree A and Tree B may be formed from the same space of data points, but in a different random manner.

FIG. 23B shows an embodiment of a technique for in-memory compute of vectors, which may be used to calculate distances between vectors. FIG. 23B depicts a technique that may be used when the dimension of the vectors is larger than n. In an embodiment, the vectors of the leaf nodes are split into sub-vectors, each with no more than n elements. A basic CE 1800 in Plane 0 is programmed with elements 1 to n of each of the vectors of a leaf node. A basic CE 1800 in Plane 1 is programmed with elements n+1 to 2n of each of the vectors of the leaf node. Additional planes may be used if the vectors are larger than 2n. The memory system computes a distance between an input vector and the vectors of the leaf node in parallel. The signals for elements 1 to n of the input vector are applied to the basic CE 1800 in Plane 0 at substantially the same time as applying the signals for elements n+1 to 2n of the input vector are to the basic CE 1800 in Plane 1. The sense circuitry 1810 on plane 0 senses the signals on the bit lines connected to the basic CE 1800 in Plane 0 at substantially the same time as the sense circuitry 1810 on plane 1 senses the signals on the bit lines connected to the basic CE 1800 in Plane 1. Results of the sensing may be sent to the memory controller 120, which may aggregate the results. This concept may be extended to many more planes, wherein vectors of a larger dimension may be handled.

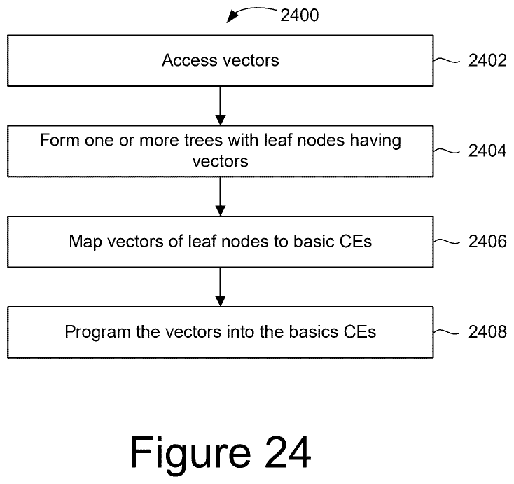

FIG. 24 is a flowchart of one embodiment of a process 2400 of mapping vectors to basic CEs. The process 2400 may be performed within storage system 100 or accelerator card 1700 but is not limited thereto. Step 2402 includes access vectors. The vectors may be accessed from a vector database in, for example, storage die 1710. Step 2404 includes forming one or more trees with leaf nodes having vectors. In an embodiment a tree such as tree 1600 in FIG. 16 is formed. The tree 1600 may have a root node 1601, a number of intermediate nodes 1602 and a number of leaf nodes 1604. In one aspect, an ANNOY technique is used to form the tree. However, ANNOY is not required. In one embodiment, the tree is a 2-way tree. Step 2404 also includes storing the one or more trees as data structures in non-transitory memory. In one embodiment, the trees are stored in NAND memory cells in a storage die 1710. Storing the trees includes storing metadata about the various nodes in the trees. The memory controller 120 is able to access the trees from the NAND memory cells in a storage die 1710 and load a portion of the trees into local memory 140.

Step 2406 includes mapping vectors from the leaf nodes to basic CEs in the memory system. Step 2406 may include mapping each vector to one or more bit lines. For example, if the entire vector fits in one basic CE then the vector may be mapped to one bit line. However, if the vector is to large to fit into one basic CE then the vector may be mapped to more than one bit line (with the bit lines being in different planes). Numerous mapping techniques have been described in connection with FIGS. 13A, 13B, 18, 19, 20, 21, 22, 23A, and 23B. Step 2408 includes programming the vectors into the basic CEs in accordance with the mapping.

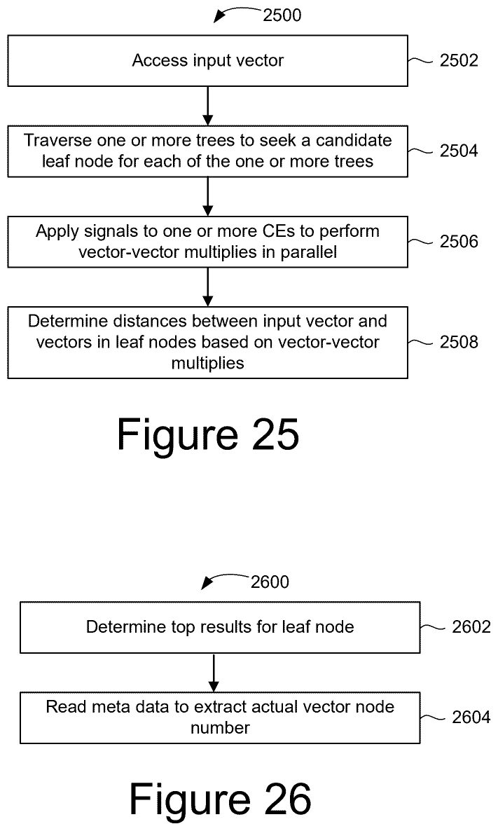

FIG. 25 is a flowchart of one embodiment of a process 2500 of an ANN search. The process 2400 may be performed within storage system 100 or accelerator card 1700 but is not limited thereto. Prior to process 2500, the vectors are programmed into the basic CEs. Step 2502 includes accessing an input vector. This vector may be a vector for which a nearest neighbor is to be located. Step 2504 includes traversing one or more trees to seek a candidate leaf node for each of the one or more trees. FIG. 16 depicts one example of how a tree may be traversed through intermediate nodes to a leaf node. Step 2504 may include reading a portion of the tree 1600 from NAND memory cells. One or more reads of NAND may be performed. Each read could read the metadata associated with a number of the nodes of the tree 1600. In one embodiment, the metadata is loaded into local memory 140 of the memory controller 120. The memory controller 120 then processes the metadata to determine how to traverse the tree 1600. As noted above the metadata for the intermediate nodes 1602 may contain information about hyperplanes, which describe the division of the space 1502. Step 2504 may also include identifying one or more basic CEs that are associated with the candidate leaf node(s). The basic CEs 1800 may be described in metadata in the leaf nodes.

Step 2506 includes applying signals to one or more CEs to perform vector-vector multiplication in parallel. Examples of applying signals to one or more CEs to perform vector-vector multiplication in parallel are shown and described with respect to FIGS. 13A, 13B, 18, 19, 23A, and 23B. Step 2508 includes determining distances between the input vector and vectors in the leaf nodes based on the vector-vector multiplication.

FIG. 26 is a flowchart of one embodiment of a process 2600 that shows further details of determining distances between the input vector and vectors in a leaf node based on the vector-vector multiplication. Process 2600 may be used in an embodiment of step 2508. The process 2600 may be repeated for each leaf node processed in step 2508. Step 2602 includes determining top results for the leaf node. As one example, the memory system may extract the top 5 or 10 shortest distances between the input vector and the respective vectors in the leaf node. Step 2604 includes reading meta data to extract the actual vector node number for the candidates having the shortest distances.

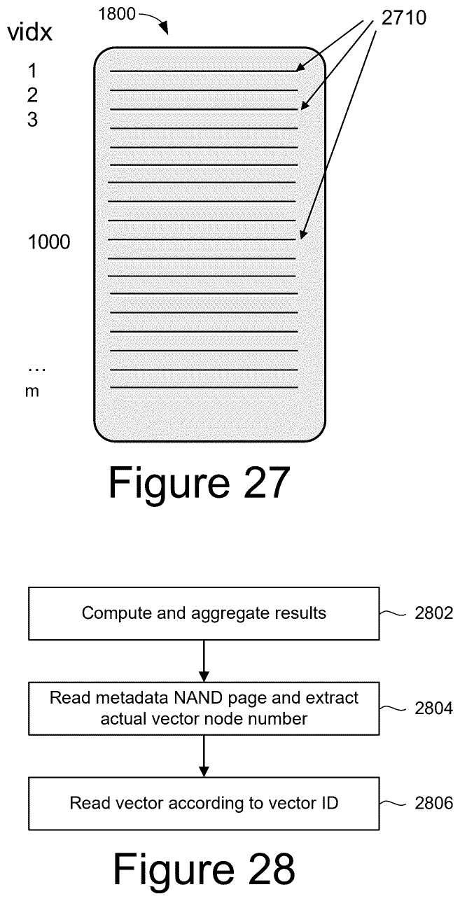

FIG. 27 illustrates how vectors of leaf node may be stored in a basic CE 1800. Up to m vectors 2710 are stored in the basic CE 1800. Each vector has a vector ID (vidx), which may be stored in metadata in one of the storage dies 1710. In an embodiment, the metadata for a leaf node has the following format:

### <Leaf Node, Vector_idx_list>

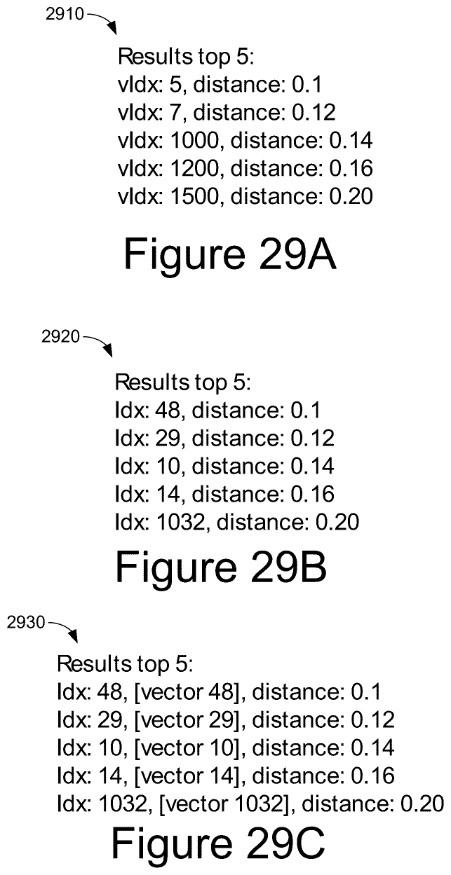

FIG. 28 is a flowchart of an embodiment of a process of locating actual vectors based on the computation results. Step 2802 includes computing and aggregating results of vector-vector multiplication in the basic CEs. FIG. 29A depicts one example of results after step 2802. A list of top results 2910 is depicted. Each entry in the list has a vector ID (vidx) and a distance. The memory system determines the distance based on the result of the multiplication of the input vector by the vector stored in the basic CE 1800. Step 2804 in FIG. 28 includes reading metadata in a NAND page and extracting an actual node number. Step 2804 may include the memory controller 120 sending a command to a storage die 1710 to read one or more pages in NAND. FIG. 29B depicts one example of results after step 2804. The top results 2920 now depict an actual vector ID (idx) and the associated distance. Step 2806 in FIG. 28 includes reading the vector according to the vector ID. Step 2806 may include the memory controller 120 sending a command to a storage die 1710 to read one or more pages in NAND. FIG. 29C depicts one example of results after step 2806. The top results 2930 include the actual vectors, along with the vector IDs and the associated distances. In an embodiment, the memory controller 120 returns the results depicted in FIG. 29C to the host 102.

In view of the foregoing, an embodiment includes an apparatus comprising one or more control circuits configured to connect to a plurality of planes. Each plane comprises a three-dimensional memory structure having NAND strings extending in a z-direction and word line layers each extending in an x-y plane. The one or more control circuits are configured to access one or more trees from non-transitory memory in which each leaf node in the one or more trees comprises a plurality of vectors. Each tree is a data structure. The one or more control circuits are configured to map the vectors of the leaf nodes of the one or more trees to a plurality of basic compute engines. Each basic compute engine comprises NAND memory cells on a single plane of the plurality of planes. The one or more control circuits are configured to program the vectors of the leaf nodes of the one or more trees into the plurality of basic compute engines in accordance with the mapping. The one or more control circuits are configured to perform an in-memory vector-vector multiplication in parallel between an input vector and each of the vectors of one or more of the leaf nodes in one or more of the basic compute engines.

In a further embodiment, each of the basic compute engines comprises an m×n kernel. The one or more control circuits are configured to process the one or more trees until each leaf node in the one or more trees comprises no more than m vectors.

In a further embodiment, the one or more control circuits are configured to program all vectors of a particular leaf node entirely into a single basic compute engine responsive to a vector dimension for vectors in the particular leaf node being no larger than n.

In a further embodiment, the one or more control circuits are configured to program all vectors of “z” leaf nodes of a corresponding z trees into the same basic compute engine responsive to a total number of vectors in the “z” leaf nodes being no greater than m, wherein z is an integer greater than 1.

In a further embodiment, the one or more control circuits are configured to split each vector of a particular leaf node into “p” sub-vectors responsive to a vector dimension for vectors in the particular leaf node being larger than n. Each sub-vector has a dimensional no larger than n. The sub-vectors include “p” sets of sub-vectors, wherein p is an integer greater than 1. The one or more control circuits are configured to program each set of the “p” sets of sub-vectors into a basic compute engine in a different plane of the plurality of planes.

In a further embodiment, the one or more control circuits are further configured to apply signals representing the input vector to the one or more basic compute engines. The one or more control circuits are further configured to sense signals from the one or more basic compute engines in response to the signals representing the input vector to perform a plurality of vector-vector multiplications in parallel. The one or more control circuits are further configured to determine distances between the input vector and the vectors programmed into the one or more basic compute engines based on the plurality of vector-vector multiplications.

In a further embodiment, each of the basic compute engines comprises an m×n kernel; m extends in a word line layer direction in the three-dimensional memory structures in a set of the planes; and n extends a NAND string direction in the three-dimensional memory structures in the set of the planes.

In a further embodiment, the one or more control circuits are configured to apply signals representing the input vector to word lines of the one or more of the basic compute engines. The one or more control circuits are configured to sense signals from bit lines associated with the one or more of the basic compute engines in response to the signals representing the input vector to perform the in-memory vector-vector multiplication in parallel. The one or more control circuits are configured to determine distances between the input vector and the vectors of the leaf nodes in the one or more of the basic compute engines based on the signals sensed from the bit lines.

In a further embodiment, each of the basic compute engines comprises an m×n kernel; m extends in a first word line layer direction in the three-dimensional memory structures in a set of the planes; and n extends a second word line layer direction in the three-dimensional memory structures in the set of the planes, the second word line layer direction being perpendicular to the first word line layer direction.

In a further embodiment, the one or more control circuits are configured to apply signals representing an input vector to drain side select lines of the one or more of the basic compute engines. The one or more control circuits are configured to sense signals from bit lines associated with the one or more of the basic compute engines in response to the signals representing the input vector to perform the in-memory vector-vector multiplication in parallel. The one or more control circuits are configured to determine distances between the input vector and the vectors of the one or more leaf nodes in the one or more of the basic compute engines based on the signals sensed from the bit lines.

In a further embodiment, the one or more control circuits are configured to perform the in-memory vector-vector multiplication in parallel between the input vector and each of the vectors of the one or more leaf nodes in a plurality of basic compute engines, wherein each of the plurality of basic compute engines resides on a different plane of the plurality of planes.

In a further embodiment, each of the basic compute engines comprises an m×n kernel. The one or more control circuits are configured to create the one or more trees from a space of data points such that the leaf nodes each contain no more than m of the data points.

An embodiment includes a method for operating a NAND memory system. The method comprises creating one or more trees each having intermediate nodes and leaf nodes. Each leaf node has a plurality of vectors but no more vectors than a number of bit lines in a plane in the NAND memory system. Each vector has “i” elements, wherein i is an integer greater than 1. The method comprises storing the one or more trees in non-transitory memory, each tree being a data structure. The method comprises mapping, for each respective leaf node in the one or more trees, each vector in the respective leaf node to one or more bit lines in the NAND memory system. The method comprises programming, for each respective vector in the one or more trees, NAND memory cells associated with the one or more bit lines associated with the respective vector to represent the i elements of the respective vector. The method comprises identifying one or more candidate leaf nodes in the one or more trees based on an input vector having i elements. The method comprises applying signals to NAND strings associated with the one or more candidate leaf nodes to represent the input vector. The method comprises sensing the bit lines associated with the one or more candidate leaf nodes in parallel in response to applying the signals to represent the input vector. The method comprises determining a distance between each vector in the one or more candidate leaf nodes and the input vector based on sensing the bit lines.

An embodiment includes a NAND memory system, comprising a plurality of planes and one or more control circuits in communication with the plurality of planes. Each plane comprises NAND memory cells and a plurality of bit lines. The one or more control circuits are configured to identify a plurality of candidate leaf nodes in a set of trees. Each candidate leaf node comprises a plurality of vectors. Each tree is a data structure stored in non-transitory memory. The one or more control circuits are configured to identify one or more basic compute engines in the plurality of planes that store the vectors of the candidate leaf nodes. Each basic compute engine comprises a plurality of NAND memory cells in a single plane of the plurality of planes. Each basic compute engine is associated with the plurality of bit lines of the plane. The one or more control circuits are configured to apply signals to the one or more basic compute engines to represent an input vector. The one or more control circuits are configured to, for each respective basic compute engine of the one or more basic compute engines, sense the plurality of bit lines associated with the respective basic compute engine. The one or more control circuits are configured to determine distances between the input vector and each of the vectors in the candidate leaf nodes based on sensing the plurality of bit lines of the one or more basic compute engines.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects, but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. An apparatus comprising:
one or more control circuits configured to connect to a plurality of planes, each plane comprising a three-dimensional memory structure having NAND strings extending in a z-direction and word line layers each extending in an x-y plane, the one or more control circuits configured to:
access one or more trees from non-transitory memory in which each leaf node in the one or more trees comprises a plurality of vectors, each tree being a data structure;
map the vectors of the leaf nodes of the one or more trees to a plurality of basic compute engines, wherein each basic compute engine comprises NAND memory cells on a single plane of the plurality of planes;
program the vectors of the leaf nodes of the one or more trees into the plurality of basic compute engines in accordance with the mapping; and
perform an in-memory vector-vector multiplication in parallel between an input vector and each of the vectors of one or more of the leaf nodes in one or more of the basic compute engines.

2. The apparatus of claim 1, wherein:
each of the basic compute engines comprises an m×n kernel; and
the one or more control circuits are configured to process the one or more trees until each leaf node in the one or more trees comprises no more than m vectors.

3. The apparatus of claim 2, wherein the one or more control circuits are configured to:
program all vectors of a particular leaf node entirely into a single basic compute engine responsive to a vector dimension for vectors in the particular leaf node being no larger than n.

4. The apparatus of claim 2, wherein the one or more control circuits are configured to:
program all vectors of “z” leaf nodes of a corresponding z trees into the same basic compute engine responsive to a total number of vectors in the “z” leaf nodes being no greater than m, wherein z is an integer greater than 1.

5. The apparatus of claim 2, wherein the one or more control circuits are configured to:
split each vector of a particular leaf node into “p” sub-vectors responsive to a vector dimension for vectors in the particular leaf node being larger than n, each sub-vector having a dimensional no larger than n, the sub-vectors comprising “p” sets of sub-vectors, wherein p is an integer greater than 1; and
program each set of the “p” sets of sub-vectors into a basic compute engine in a different plane of the plurality of planes.

6. The apparatus of claim 1, wherein the one or more control circuits are further configured to:
apply signals representing the input vector to the one or more basic compute engines;
sense signals from the one or more basic compute engines in response to the signals representing the input vector to perform a plurality of vector-vector multiplications in parallel; and
determine distances between the input vector and the vectors programmed into the one or more basic compute engines based on the plurality of vector-vector multiplications.

7. The apparatus of claim 1, wherein:
each of the basic compute engines comprises an m×n kernel;
m extends in a word line layer direction in the three-dimensional memory structures in a set of the planes; and
n extends a NAND string direction in the three-dimensional memory structures in the set of the planes.

8. The apparatus of claim 7, wherein the one or more control circuits are configured to:
apply signals representing the input vector to word lines of the one or more of the basic compute engines;
sense signals from bit lines associated with the one or more of the basic compute engines in response to the signals representing the input vector to perform the in-memory vector-vector multiplication in parallel; and
determine distances between the input vector and the vectors of the leaf nodes in the one or more of the basic compute engines based on the signals sensed from the bit lines.

9. The apparatus of claim 1, wherein:
each of the basic compute engines comprises an m×n kernel;
m extends in a first word line layer direction in the three-dimensional memory structures in a set of the planes; and
n extends a second word line layer direction in the three-dimensional memory structures in the set of the planes, the second word line layer direction being perpendicular to the first word line layer direction.

10. The apparatus of claim 9, wherein the one or more control circuits are configured to:
apply signals representing an input vector to drain side select lines of the one or more of the basic compute engines; and
sense signals from bit lines associated with the one or more of the basic compute engines in response to the signals representing the input vector to perform the in-memory vector-vector multiplication in parallel; and
determine distances between the input vector and the vectors of the one or more leaf nodes in the one or more of the basic compute engines based on the signals sensed from the bit lines.

11. The apparatus of claim 1, wherein the one or more control circuits are configured to:
perform the in-memory vector-vector multiplication in parallel between the input vector and each of the vectors of the one or more leaf nodes in a plurality of basic compute engines, wherein each of the plurality of basic compute engines resides on a different plane of the plurality of planes.

12. The apparatus of claim 1, wherein:
each of the basic compute engines comprises an m×n kernel; and
the one or more control circuits are configured to create the one or more trees from a space of data points such that the leaf nodes each contain no more than m of the data points.

13. The apparatus of claim 1, wherein the one or more control circuits are configured to:
perform an approximate nearest neighbor search in a plurality of the one or more trees in parallel by performing the in-memory vector-vector multiplication in parallel between the input vector and each of the vectors of one or more of the leaf nodes in the one or more of the basic compute engines; and
select a top set of results from the approximate nearest neighbor searches in the plurality of the one or more trees.

14. A method for operating a NAND memory system, the method comprising:
creating one or more trees each having intermediate nodes and leaf nodes, each leaf node having a plurality of vectors but no more vectors than a number of bit lines in a plane in the NAND memory system, each vector having “i” elements, wherein i is an integer greater than 1;
storing the one or more trees in non-transitory memory, each tree being a data structure;
mapping, for each respective leaf node in the one or more trees, each vector in the respective leaf node to one or more bit lines in the NAND memory system;
programming, for each respective vector in the one or more trees, NAND memory cells associated with the one or more bit lines associated with the respective vector to represent the i elements of the respective vector;
identifying one or more candidate leaf nodes in the one or more trees based on an input vector having i elements;
applying signals to NAND strings associated with the one or more candidate leaf nodes to represent the input vector;
sensing the bit lines associated with the one or more candidate leaf nodes in parallel in response to applying the signals to represent the input vector; and
determining a distance between the input vector and each vector in the one or more candidate leaf nodes based on sensing the bit lines.

15. The method of claim 14, wherein programming, for each respective vector, NAND memory cells associated with the bit line associated with the respective vector to represent the i elements of the respective vector includes:
programming, for a particular vector, memory cells on the same NAND string responsive to all elements of the particular vector fitting on the same NAND string.

16. The method of claim 14, wherein programming, for each respective vector, NAND memory cells associated with the bit line associated with the respective vector to represent the i elements of the respective vector includes:
programming, for a particular vector, memory cells on NAND strings in different planes responsive to the number of elements being too large to fit on a single NAND string.

17. The method of claim 14, wherein programming, for each respective vector, NAND memory cells associated with the bit line associated with the respective vector to represent the i elements of the respective vector includes:
programming, for a particular vector, memory cells on different NAND strings in the same plane that are associated with the same bit line.

18. A NAND memory system, comprising:
a plurality of planes, each plane comprising NAND memory cells and a plurality of bit lines; and
one or more control circuits in communication with the plurality of planes, the one or more control circuits configured to:
identify a plurality of candidate leaf nodes in a set of trees, each candidate leaf node comprises a plurality of vectors, each tree being a data structure stored in non-transitory memory;
identify one or more basic compute engines in the plurality of planes that store the vectors of the candidate leaf nodes, wherein each basic compute engine comprises a plurality of NAND memory cells in a single plane of the plurality of planes, wherein each basic compute engine is associated with the plurality of bit lines of the plane;
apply signals to the one or more basic compute engines to represent an input vector;
for each respective basic compute engine of the one or more basic compute engines, sense the plurality of bit lines associated with the respective basic compute engine; and
determine distances between the input vector and each of the vectors in the candidate leaf nodes based on sensing the plurality of bit lines of the one or more basic compute engines.

19. The NAND memory system of claim 18, wherein:
the one or more basic compute engines that store the vectors of the candidate leaf nodes include a basic compute engine on each plane of a set of the plurality of planes;
the one or more control circuits apply the signals to the one or more basic compute engines on each plane of the set of the plurality of at substantially the same time; and
the one or more control circuits sense the plurality of bit lines associated with the respective basic compute engines at substantially the same time.

20. The NAND memory system of claim 18, wherein the one or more control circuits are configured to:
determine a set of shortest distances between the input vector and the vectors of a particular leaf node; and
access metadata from a group of NAND memory cells to extract actual vector node numbers for the vectors having the shortest distances to the input vector.
